(19) United States
(12) Patent Application Publication
(10) Pub. No.: US 2017/0111996 A1
(43) Pub. Date: Apr. 20, 2017

(54) NON-TRANSITORY COMPUTER-READABLE RECORDING MEDIUM HAVING STORED THEREIN DESIGN ASSIST PROGRAM, INFORMATION PROCESSING DEVICE, AND METHOD FOR ASSISTING DESIGN

(71) Applicant: FUJITSU LIMITED, Kawasaki-shi (JP)

(72) Inventor: Tomoyuki NAKAO, Yokohama (JP)

(73) Assignee: FUJITSU LIMITED, Kawasaki-shi (JP)

(21) Appl. No.: 15/270,048

(22) Filed: Sep. 20, 2016

(30) Foreign Application Priority Data
Oct. 16, 2015 (JP) 2015-204585

(51) Int. Cl. H05K 3/00; G06F 17/50; H05K 1/02

(52) U.S. Cl. CPC H05K 3/0005; H05K 1/023; G06F 17/5068; G06F 2217/82

(57) ABSTRACT

In a memory, an association, for each component, among a source pin being a source of generating the electromagnetic noise, a suppression candidate pin on which a measure against the electromagnetic noise generated by the source pin is to be taken, and a noise amount of noise acting on the suppression candidate pin and being originated from the electromagnetic noise generated at the source pin is stored. On the basis of the association, a processor extracts a suppression candidate pin having a noise amount equal to or larger than a predetermined value as a suppression target pin for which the suppression component is to be arranged from a plurality of the suppression candidate pins, and outputs, from an output device, information about the suppression target pin extracted. This configuration takes a measure to suppress electromagnetic noise regardless the skill of the designer.

### CROSS-REFERENCE TO RELATED APPLICATION

This application is based upon and claims the benefit of priority of the prior Japanese application No. 2015-204585 filed on Oct. 16, 2015 in Japan, the entire contents of which are hereby incorporated by reference.

### FIELD

The embodiment discussed herein relates to a non-transitory computer-readable recording medium having stored therein design assist program, an information processing device, and a method for assisting design.

### BACKGROUND

On a printed board mounted on an electronic device, various components such as an Integrated Circuit (IC) are arranged. To the clock pin and the power-source pin of each arranged component, a clock signal pattern and a power-source pattern are connected, respectively.

With this configuration, the clock signal from a clock oscillator (OSC) is supplied to the clock pin of each component through the clock signal pattern while the power from a power source is supplied to the power-source pin of each component through the power-source pattern.

In this occasion, a clock signal pattern and a power-source pattern on a printed board emit electromagnetic wave acting as electromagnetic noise. Such electromagnetic noise has a possibility of affecting another electronic device and a human body around the electronic device. To avoid the suppression of radiation of electromagnetic noise, electromagnetic noise suppression components are arranged in the vicinity of the clock pin and the power-source pin on a printed board.

An example of an electromagnetic noise suppression component is a bead or a capacitor. A bead includes a coil and resistor serially coupled to each other and inhibits, when being serially coupled on the clock signal line, the noise from flowing. A capacitor bypasses the noise when being interposed between and coupled both to the power source and the ground. Hereinafter, an electronic noise suppression component may sometimes be referred to as an electro-magnetic interference (EMI) suppression component or simply a suppression component.

It is preferable that an EMI suppression component is arranged for every pin that would be an EMI suppression target. However, constrain in packaging practically makes it impossible to arrange an EMI suppression component for every pin. For the above, a circuit designer designs the circuit which reduces the number of the EMI suppression components, referring to a circuit diagram (see, for example, FIG. 4) displayed on a monitor, in order to accomplish circuit design. At that time, the circuit designer specifies the positions of arrangement, the types, and the number of EMI suppression components on the circuit diagram displayed on the monitor.

The pattern designer of the printed board designs the pattern diagram in accordance with the above circuit diagram created by the circuit designer. In the pattern diagram, all the components including EMI suppression components are arranged on a printed board and such arranged components are coupled via clock signal patterns and power-source patterns. In pattern designing, the positions of arrangement of EMI suppression component are determined by the pattern designer on his/her discretion. Consequently, a single circuit diagram is converted into multiple different pattern diagrams (see, for example, FIGS. 5 and 6) with pattern designers.

Furthermore, the circuit designer also creates a system diagram (see, for example, FIGS. 7 and 8) of a power source and a clock, which is based on the pattern diagram, in order to evaluate the arrangement of EMI suppression components in the pattern diagram created by the pattern designer. The circuit designer examines the quality of the arrangement of EMI suppression components on the basis of the generated system diagram.
[Patent Literature 1] Japanese Laid-open Patent Publication No. 2003-6260
[Patent Literature 2] Japanese Laid-open Patent Publication No. 2000-35976
[Patent Literature 3] Japanese Laid-open Patent Publication No. 2002-15023

However, the circuit design and the pattern design accomplished as the above may result in a prototype device not satisfying necessary standard in an EMI evaluation on the prototype device. This result is sometimes derived from an error in the above examination of the quality of the arrangement of EMI suppression components.

One of the possible causes of such an error in the examination of the quality of the arrangement of EMI suppression components seems that the examination of the arrangement largely depends on skills of the circuit designer and the pattern designer. For the above, an underskilled designer is incapable of arranging EMI suppression components at proper positions, which makes it impossible to inhibit radiation of electromagnetic noise. Consequently, an EMI problem (electromagnetic-noise radiation problem) may arise.

### SUMMARY

As an aspect of an embodiment, the on-transitory computer-readable recording medium having stored therein a design assist program that assists in arrangement design of a suppression component to suppress electromagnetic noise and to be disposed on a board when the board is designed by arranging a plurality of components thereon, the design assist program causing a computer to execute the following processes (1) and (2).

(1) Extracting, based on an association among a source pin that is a source of generating the electromagnetic noise, a suppression candidate pin on which a measure against the electromagnetic noise generated by the source pin is to be taken, and a noise amount of noise that acts on the suppression candidate pin and that is originated from the electromagnetic noise, the association being obtained for each of the plurality of components, a suppression candidate pin having a noise amount equal to or larger than a predetermined value as a suppression target pin for which the suppression component is to be arranged from a plurality of the suppression candidate pins.

(2) Outputting, from an output device, information about the suppression target pin from an output device extracted.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF THE DRAWINGS

FIG. 1 is a block diagram schematically illustrating an example of the functional configuration of an information processing apparatus having a design assist function (EMI suppression function) according to a first embodiment of the present invention;

FIG. 2 is a block diagram schematically illustrating an example of the hardware configuration of an information processing apparatus that achieves a design assist function (EMI suppression function) according to a first embodiment of the present invention;

FIG. 3 is a diagram illustrating an example of an EMI transfer information library (association) of the first embodiment;

FIG. 4 is a diagram illustrating an example of a circuit diagram including EMI suppression components, the circuit diagram being displayed in circuit designing of a board of the design target;

FIG. 5 is a diagram illustrating a first example of a pattern diagram of a board of the design target, the pattern diagram being designed and displayed on the basis of a circuit diagram of FIG. 4;

FIG. 6 is a diagram illustrating a second example of a pattern diagram of a board of the design target, the pattern diagram being designed and displayed on the basis of a circuit diagram of FIG. 4;

FIG. 7 is a diagram illustrating an example of a system diagram of a power source and a clock of a board of the design target, the system diagram being generated and displayed on the basis of a pattern diagram of FIG. 5;

FIG. 8 is a diagram denoting a possible EMI problem in a system diagram of a power source and a clock of FIG. 7;

FIG. 9 is a flow diagram illustrating a succession of procedural steps of arrangement designing and displaying of EMI suppression components of a traditional technique;

FIG. 10 is a flow diagram illustrating a succession of procedural steps of arrangement designing and displaying of EMI suppression components of the first embodiment;

FIG. 11 is a flow diagram illustrating a succession of procedural steps of determining whether an EMI suppression component is required in the first embodiment;

FIGS. 12 and 13 are diagrams illustrating contents of an operation table in determining whether an EMI suppression component is required in the first embodiment;

FIG. 14 is a diagram illustrating procedural steps of providing a noise transfer number in the first embodiment;

FIGS. 15-17 are diagrams illustrating contents of an operation table in determining whether an EMI suppression component is required in the first embodiment;

FIG. 18 is a diagram illustrating an example of a system diagram of a power source and a clock of a board of the design target of the first embodiment, the system diagram being generated and displayed on the basis of an operation table of FIG. 17, along with noise transfer directions and noise transfer numbers;

FIG. 19 is a diagram illustrating an example of a pattern diagram of a board of the design target of the first embodiment, the system diagram being designed on the basis of a circuit diagram of FIG. 4;

FIG. 20 is a diagram illustrating an example of a system diagram of a power source and a clock of a board of the design target of the first embodiment, the system diagram being designed on the basis of a circuit diagram of FIG. 19;

FIG. 21 is a diagram illustrating types of transferring EMI noise and procedural steps of calculating an EMI noise amount of each type of transferring;

FIG. 22 is a diagram illustrating an association between an example of generating EMI transfer information library of FIG. 2 and a type of transferring EMI noise; and

FIG. 23 is a diagram illustrating procedural steps of an EMI noise amount transferred from a source pin to a suppression candidate pin by “coupling”.

### DESCRIPTION OF THE PREFERRED EMBODIMENTS

Hereinafter, detailed description will now be made in relation to a non-transitory computer-readable recording medium having stored therein design assist program, an information processing device, and a method for assisting design by referring to the accompanying drawings. The following embodiment is exemplary, so there is no intention to exclude application of various modifications and techniques not suggested in the following description to the embodiment. Namely, various changes and modifications to the embodiment can be suggested without departing from the spirit of the present invention. The accompanying drawings do not intend to include only the elements appearing therein, but may include additional elements and functions.

### (1) Traditional Technique to be Compared with a First Embodiment

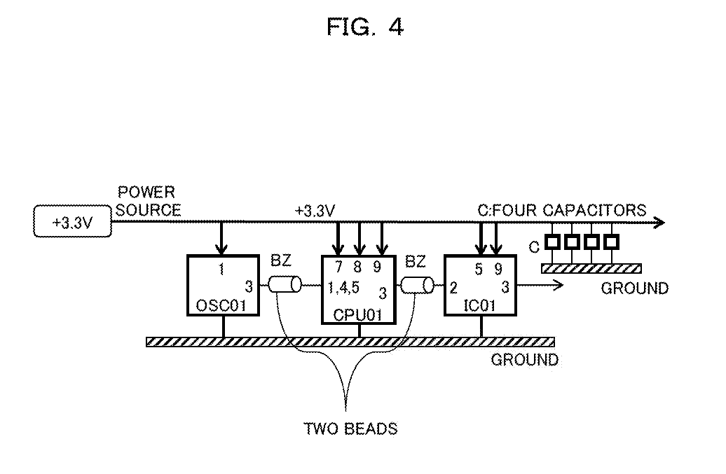

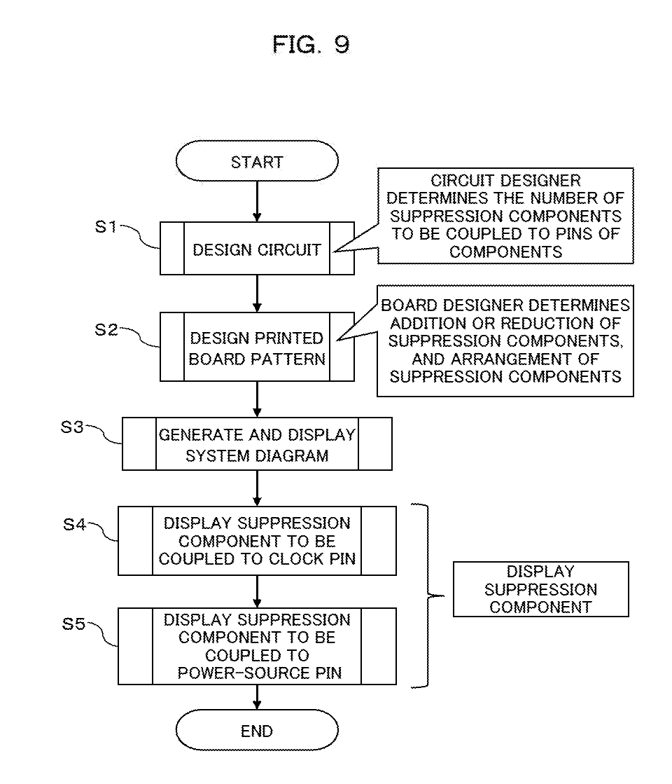

Description will now be made in relation to procedural steps of arrangement designing and displaying EMI suppression components in a traditional technique to be compared with a first embodiment along with a flow diagram (steps S1-S5) of FIG. 9 by referring to FIGS. 4-8.

First of all, a circuit designer designs a circuit of a board of the design target with reference to the monitor (step S1 of FIG. 9), and consequently generates the circuit diagram illustrated in FIG. 4. As described above, constraint in packaging practically makes the circuit designing impossible to arrange an EMI suppression component for every pin. Accordingly, the circuit designer determines the number of EMI suppression components to be coupled to pins of each component to be arranged on the board of the design target.

The circuit diagram of FIG. 4 specifies that a bead BZ is coupled to each of the two clock pins and four capacitors C are interposed between the power source (+3.3 V) and the ground. The circuit design assigns the number of capacitors C but does not specify the arrangement positions of the capacitors C. The respective arrangement positions of the capacitors C are entrusted to a pattern designer of the printed board.

Here, FIG. 4 is an example of a circuit diagram including EMI suppression components displayed when the circuit of the board of the design target is being designed. The circuit diagram of FIG. 4 includes three components of OSC01, Central Processing Unit (CPU) 01, and IC01. The terms of OSC01, CPU01 and IC01 are specification numbers (hereinafter arrangement numbers) to make arrangement for ICs corresponding to the respective components. The power source (+3.3 V) are coupled to the power-source pin (having a pin number 1) of the component OSC01, the power-source pins (having pin numbers 7, 8, and 9) of the component CPU01, and the power-source pins (having pin numbers 5 and 9) of the components IC01. The clock pin (having a pin number 3) of the component OSC01 is coupled to the clock pins (having pin numbers 1, 4, and 5) of the component CPU01 via a bead BZ. The clock pin (having a pin number 2) of the component CPU01 is coupled to the clock pin (having a pin number 2) of the component IC01 via a bead BZ. The circuit diagram specifies that four capacitors C are interposed between the power source (+3.3 V) and the ground, as described above. In FIG. 4, numbers in the blocks representing the components OSC01, CPU01, and IC01 represent pin numbers specifying respective pins in corresponding components.

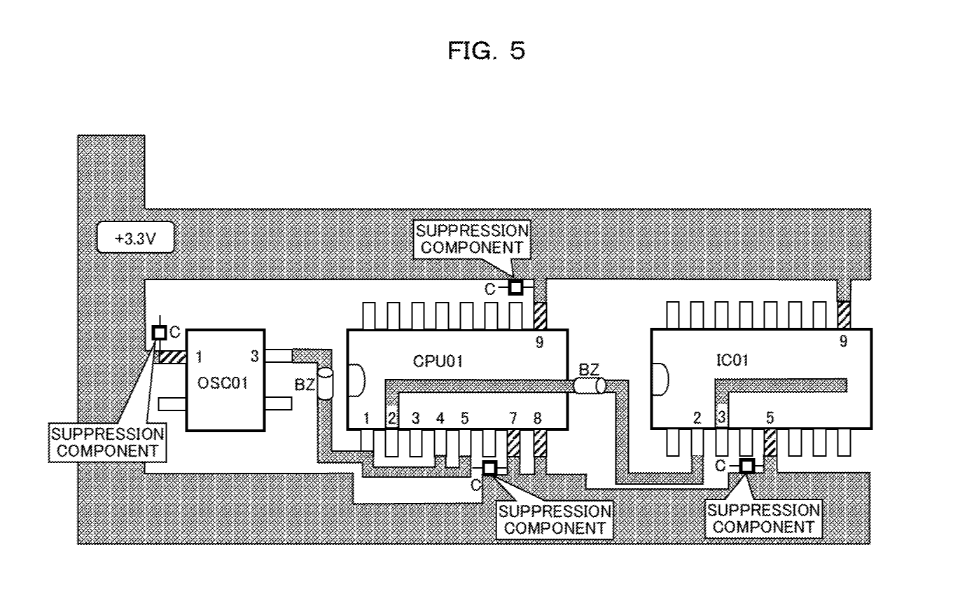

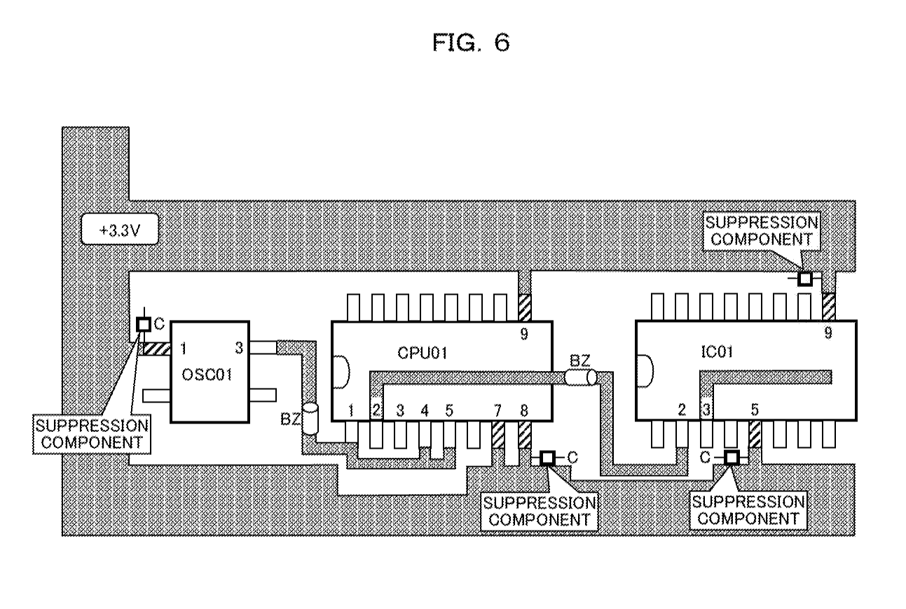

In succession, the pattern designer (board designer) of a printed board designs the pattern along the lines of the circuit diagram generated by the circuit designer with reference to the monitor (step S2 of FIG. 9), and thereby generates a pattern diagram illustrated in FIG. 5 or 6. At this time, the pattern designer examines whether the number of EMI suppression components to be arranged is increased or decreased, and determines the arrangement positions of the respective EMI suppression components. The circuit designer may be the same as or different from the pattern designer.

In the pattern diagram of FIG. 5 or 6, various components, including the EMI suppression components such as capacitors C and beads BZ, are arranged on the printed board, and the arranged components and the power source are properly coupled via clock signal patterns or power-source patterns. In this arrangement, the arrangement positions of the capacitors C on the pattern diagram are determined by the pattern designer by himself/herself. Consequently, there is a possibility that different pattern diagrams may be generated from a single circuit diagram, depending on respective pattern designers.

FIGS. 5 and 6 illustrate a first example and a second example of the pattern diagram of a board of the design target, the pattern diagram being designed and displayed on the basis of the circuit diagram of FIG. 4.

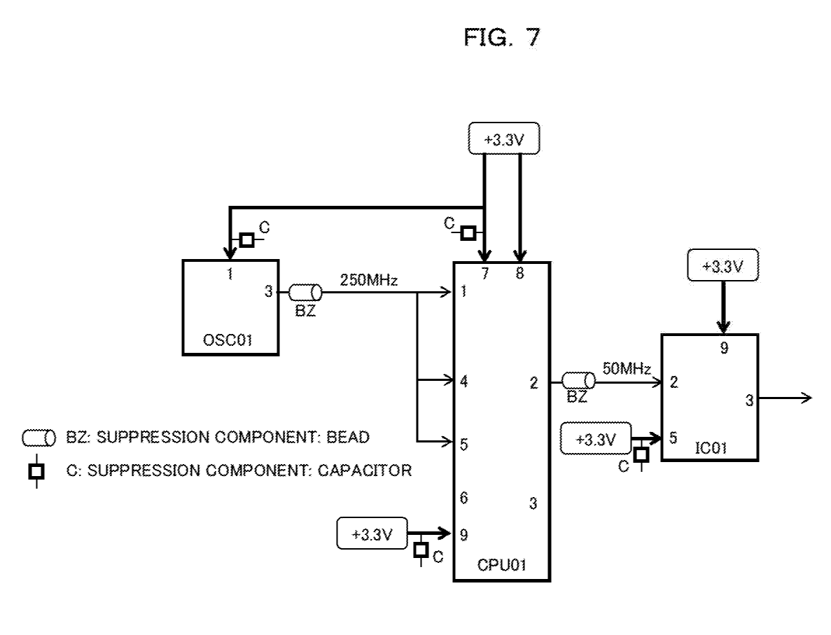

Furthermore, the circuit designer generates a system diagram of a power source and a clock illustrated in FIG. 7 from, for example, the pattern diagram of FIG. 5 and displays the system diagram in order to evaluate the arrangement of the EMI suppression components in the pattern diagram designed by the pattern designer (step S3 of FIG. 9). FIG. 7 is an example of a system diagram of a power source and a clock on the board of the design target generated from the pattern diagram of FIG. 5 and displayed. A system diagram of a power source and a clock may sometimes be abbreviated to a system diagram.

In the system diagram of FIG. 7 generated as the above, the EMI suppression components (beads BZ) to be coupled to the clock pins are displayed (step S4 of FIG. 9), and the EMI suppression components (capacitors C) to be coupled to the power-source pins are displayed (step S5 of FIG. 9). Then the circuit designer evaluates the arrangement of the EMI suppression components with reference to the system diagram displaying thereon the EMI suppression components.

As described above, the evaluation of the arrangement of the EMI suppression components made by referring to the system diagram including the EMI suppression components as illustrated in FIG. 7 largely depends on the skills of the circuit designer and the pattern designer. For the above, EMI suppression components are not able to be arranged at the respective proper positions, which fails to inhibit electromagnetic noise from radiating. Consequently, an EMI problem may arise. Hereinafter, the electromagnetic noise may be referred to as EMI noise.

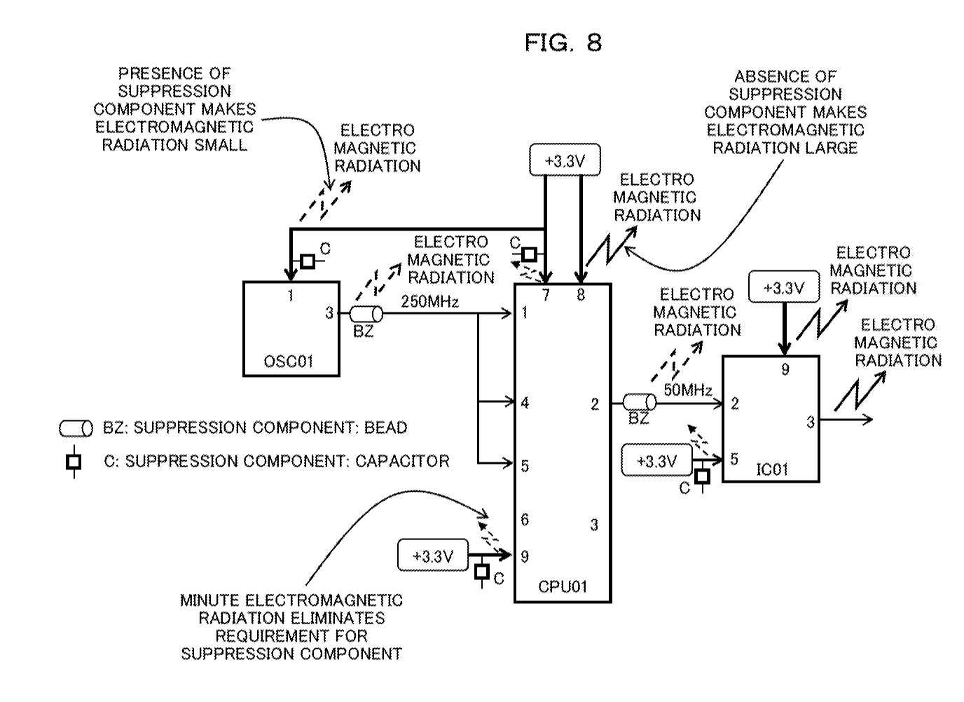

FIG. 8 is a diagram denoting a possible EMI problem occurred in the system diagram of FIG. 7. Even if the circuit designer determines that the arrangement of the EMI suppression components in the system diagram of FIG. 7 is fine, there is a possibility that the EMI suppression components are not properly arranged, leading to occurrence of an EMI problem as denoted in FIG. 8.

In the example of FIG. 8, arranging a capacitor C at the power-source pin (having a pin number 1) of the component OSC01 inhibits radiation of electromagnetic wave and consequently reduces an amount of electromagnetic radiation (an amount of radiation of EMI noise). Likewise, arranging beads BZ at the clock pin (having a pin number 3) of the component OSC01 and the clock pin (having a pin number 2) of the component CPU01 inhibits radiation of electromagnetic wave and consequently reduces an amount of electromagnetic radiation (an amount of radiation of EMI noise).

In contrast, the absence of a suppression component at the power-source pin (having a pin number 8) of the component CPU01 and at the clock pin (having a pin number 3) and the power-source pin (having a pin number 9) the component IC01 may cause an EMI problem because the electromagnetic radiation amount is large. Although capacitors C are arranged at the power-source pins (having pin numbers 7 and 9) of the component CPU01 and the power-source pin (having a pin number 5) of the component IC01, these power-source pins each radiate a minute amount of electromagnetic wave and therefore do not require EMI suppression components, which means that these EMI suppression components are unnecessarily arranged.

### (2) Overview of the First Embodiment

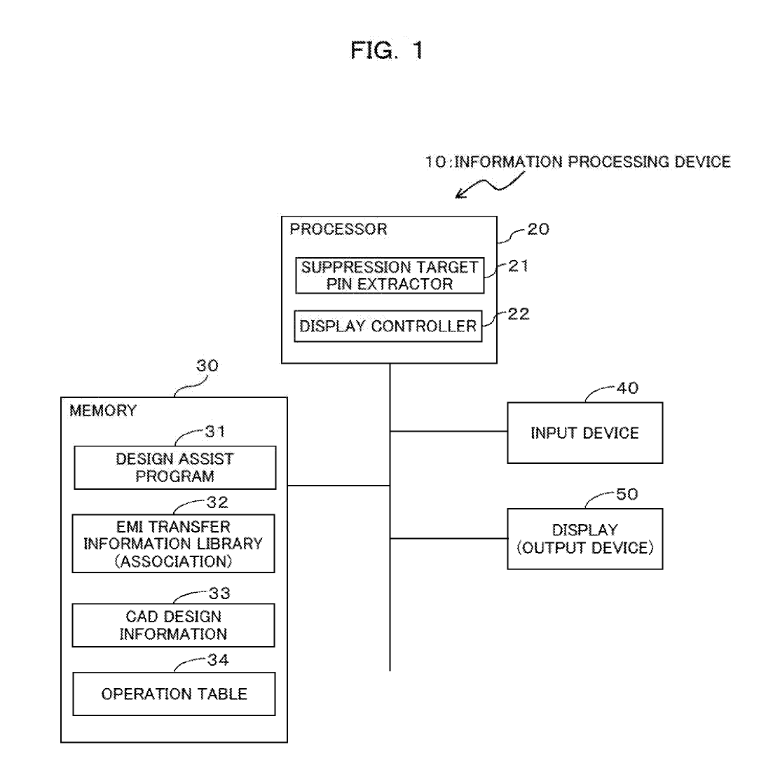

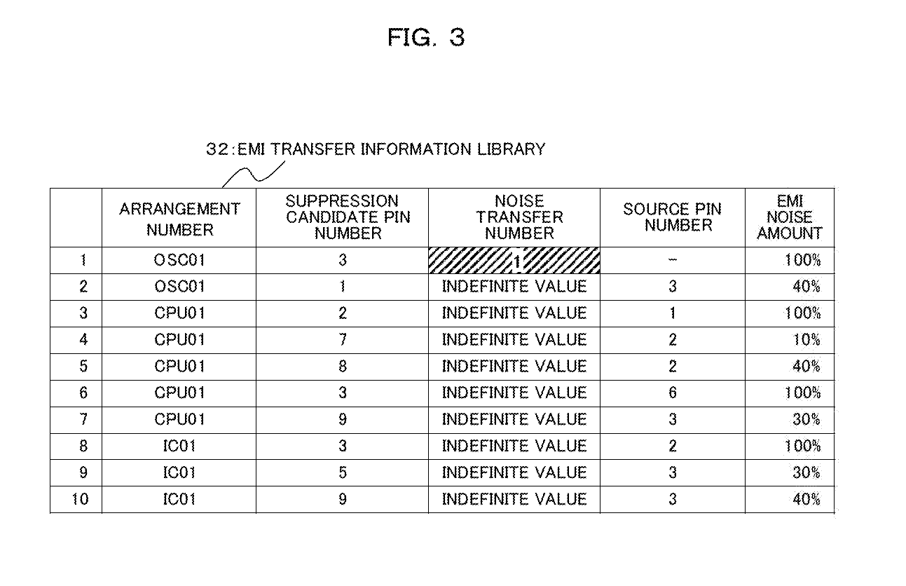

Here, the association of each component arranged on the board of the design target is provided in the form of an EMI transfer information library 32 (see FIGS. 1 and 3). The EMI transfer information library 32 retains, for each component, an association among a source pin that is a source of generating the electromagnetic noise, a suppression candidate pin on which a measure against the electromagnetic noise generated by the source pin is to be taken, and a noise amount of noise that acts on the suppression candidate pin and that is originated from the electromagnetic noise generated by the source pin, the association being in the form of a library. This means that the EMI transfer information library 32 takes a form of a library that retains the information of EMI noise generated at a source pin and transferred to a suppression component pin within each component.

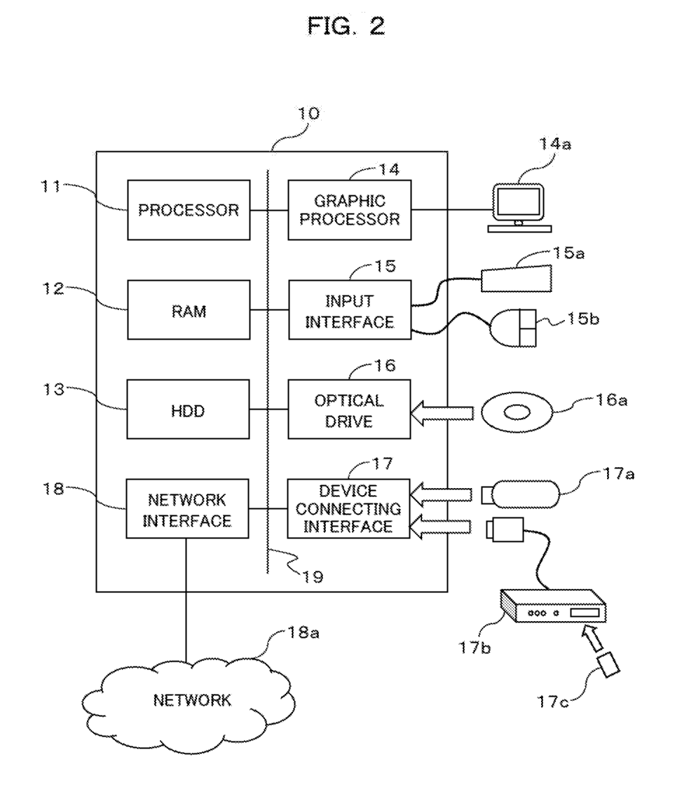

On the basis of the EMI transfer information library 32, a suppression candidate pin having a noise amount equal to or larger than a predetermined threshold is extracted as a suppression target pin at which an EMI suppression component is to be arranged. The information of the extracted suppression target pin is output from an output device to the designers, such as the circuit designer and the pattern designer. Examples of the output device are a display 50 or the monitor 14a to be described below by referring to FIGS. 1 and 2, and a printing device such as a printer. The information of the extracted suppression target pin may be displayed and output onto the pattern diagram or the system diagram of a power source and a clock. In other words, information of excess or shortage of EMI suppression components for each pin in the pattern diagram or the system diagram of a power-source and a clock may be displayed and output.

Consequently, designers such as the circuit designer and the pattern designer can grasp the excess or shortage of an EMI suppression component for each pin by referring to the pattern diagram or the system diagram of a power-source and a clock output from the output device. Accordingly, a measure against of the EMI noise can be taken irrespective of the skill of the designer, so that occurrence of an EMI problem (electromagnetic noise radiation problem) can be efficiently prohibited.

### (3) Hardware Configuration of an Information Processing Device of the First Embodiment that Achieves the Design Assisting Function

First of all, description will now be made in relation to the hardware configuration of an information processing device (computer) 10 that achieves the design assist function (or EMI suppression function) of the first embodiment with reference to FIG. 2. FIG. 2 is a block diagram schematically illustrating an example of the hardware configuration.

For example, the computer 10 includes a processor 11, a Random Access Memory (RAM) 12, a Hard Disk Drive (HDD) 13, a graphic processor 14, an input interface 15, an optical drive 16, a device connecting interface 17, and network interface 18. The functional elements 11-18 are communicably coupled to one another via a bus 19.

The processor 11 controls the entire of the computer 10. The processor 11 may be a multi-processor. Examples of the processor 11 are a Central Processing Unit (CPU), a Micro Processing Unit (MPU), a Digital Signal Processor (DSP), an Application Specific Integrated Circuit (ASIC), a Programmable Logic Device (PLD), and a Field Programmable Gate Array (FPGA). Further alternatively, the processor 11 may be a combination of two or more of a CPU, an MPU, a DSP, an ASIC, a PLD, and an FPGA.

The RAM (memory) 12 is used as the main memory of the computer 10. In the RAM 12, at least one of an Operating System (OS) program and one or more application programs executed by the processor 11 is temporarily stored. Various pieces of data to be used in the process of the processor 11 are also stored in the RAM 12. The application programs may include a design assist program (EMI suppression program, see reference number 31 of FIG. 1) that the processor 11 executes to achieve the design assist function (EMI suppression function) of the first embodiment in the computer 10.

The HDD (memory) 13 magnetically writes and reads data into and from a built-in disk. The HDD 13 is used as an auxiliary memory of the computer 10. In the HDD 13, the OS program, one or more application programs, and various pieces of data are stored. A semiconductor memory (Solid State Drive (SSD)) such as a flash memory may alternatively be used as an auxiliary memory.

The graphic processor 14 is coupled to a monitor (display, output device) 14a. The graphic processor 14 displays an image on the screen of the monitor 14a in obedience to an instruction of the processor 11. An example of the monitor 14a are a display device using a Cathode Ray Tube (CRT) and a Liquid Crystal Display.

To the input interface 15, a keyboard 15a and the mouse 15b are coupled. The input interface 15 transmits signals from the keyboard 15a and the mouse 15b to the processor 11. In particular, the mouse 15b is an example of a pointing device, and may be replaced with another pointing device, which is exemplified by a touch panel, a tablet terminal, a touch pad, or a trackball.

The optical drive 16 reads data recorded in an optical disk 16a, utilizing, for example, laser light. An optical disk 16a is a non-transitory portable recording medium having recorded therein data in a readable manner. Examples of the optical disk 16a are a Digital Versatile Disk (DVD), a DVD-RAM, a Compact Disc Read Only Memory (CD-ROM), and CD-Recordable/Rewritable (CD-R/RW).

The device connecting interface 17 is a communication interface to couple a peripheral device to the computer 10. For example, to the device connecting interface 17, a memory device 17a and a memory reader-writer 17b can be coupled. The memory device 17a is a non-transitory recording medium having a communication function with the device connecting interface 17 and is exemplified by a Universal Serial Bus (USB) memory. The memory reader-writer 17b writes data into a memory card 17c and reads data from the memory card 17c. The memory card 17c is a card-type non-transitory recording medium.

The network interface 18 is coupled to the network 18a. The network interface 18 transmits and receives data to and from another computer and a communication device via the network 18a.

The computer 10, which has the above hardware configuration, achieves the design assist function (EMI suppression function) of the first embodiment that will be detailed below with reference to FIGS. 1 and 3.

The computer 10 achieves the design assist function (EMI suppression function) of the first embodiment by executing a program (e.g., design assist program 31 to be detailed below) stored in a non-transitory computer-readable recording medium. The program to be executed by the computer 10 may be stored in various recording mediums. For example, the program to be executed by the computer 10 may be stored in the HDD 13. The processor 11 loads at least part of the programs stored in the HDD 13 into the RAM 12 and executes the loaded programs.

Alternatively, the program to be executed by the computer 10 (processor 11) may be stored in another non-transitory portable recording medium such as the optical disk 16a, the memory device 17a, and the memory card 17c. The program stored in such a portable recording medium is installed into the HDD 13 under the control of, for example, the processor 11 and then comes to be executable. Alternatively, the processor 11 may execute the program by directly reading from a portable recording medium.

### (4) Functional Configuration of an Information Processing Device of the First Embodiment that has the Design Assisting Function

Next, description will now be made in relation to the functional configuration of the information processing device (computer) 10 having the design assist function (EMI suppression function) of the first embodiment with reference to FIGS. 1 and 3. FIG. 1 is a block diagram schematically illustrating an example of the functional configuration and FIG. 3 is a diagram illustrating an example of an EMI transfer information library (association) 32 of the first embodiment.

The computer 10 exercises the function that assists in arrangement design of EMI suppression components on the board of the design target when the board is designed by arranging a plurality of components thereon. For this purpose, the computer 10 has at least functions as a processor 20, a memory 30, an input device 40, and a display 50 as illustrated in FIG. 1. Here, an example of the board of the design target is a printed board, and examples of the component to be arranged on the board are components of OSC01, CPU01, and IC01 described above with reference to FIG. 4.

The processor 20 corresponds to, for example, the processor 11 of FIG. 2. The processor 20 functions as a suppression target pin extractor 21 and a display controller 22 by executing the design assist program 31.

The memory 30 corresponds to, for example, the RAM 12 and the HDD 13 of FIG. 2, and stores and retains various pieces of data used to achieve the design assist function (EMI suppression function). Examples of the information to be stored are the design assist program 31, the EMI transfer information library 32, CAD design information 33, and an operation table 34.

As described above, the design assist program 31 causes the processor 20 (processor 11) to function as the suppression target pin extractor 21 and the display controller 22.

Also as described above, the EMI transfer information library 32 retains, for each component, an association among a source pin that is a source of generating the electromagnetic noise, a suppression candidate pin on which a measure against the electromagnetic noise generated by the source pin is to be taken, and a noise amount of noise that acts on the suppression candidate pin and that is originated from the electromagnetic noise generated at the source pin, the association being in the form of a library. One example of the EMI transfer information library 32 is illustrated in FIG. 3.

The EMI transfer information library 32 of FIG. 3 retains, for example, the EMI transfer information of the pins of the three components of OSC01, CPU01, and IC01 in the circuit diagram of FIG. 4 in the form of the library. In the EMI transfer information library 32, an arrangement number, a suppression candidate pin number, a noise transfer number, a source pin number, and an EMI noise amount are associated with one another and registered as the EMI transfer information (association).

Here, an arrangement number means a specification number to make an arrangement for an IC corresponding to each component, as described above. The three components of the first embodiment have arrangement numbers OSC01, CPU01, and IC01.

A suppression candidate pin number is a number to specify a suppression candidate pin for which requirement for an EMI suppression component has to be examined in each component. Here, a pin number corresponds to a number described in a block representing each component illustrated in the circuit diagram, the pattern diagram, and the system diagram of a power source and a clock.

The noise transfer number represents a number in which sequential order the EMI noise is transferred to the suppression candidate pin having a corresponding suppression candidate pin number. In other words, the noise transfer number represents a sequential order of transferring the EMI noise, which corresponds to an order of coupling of the components.

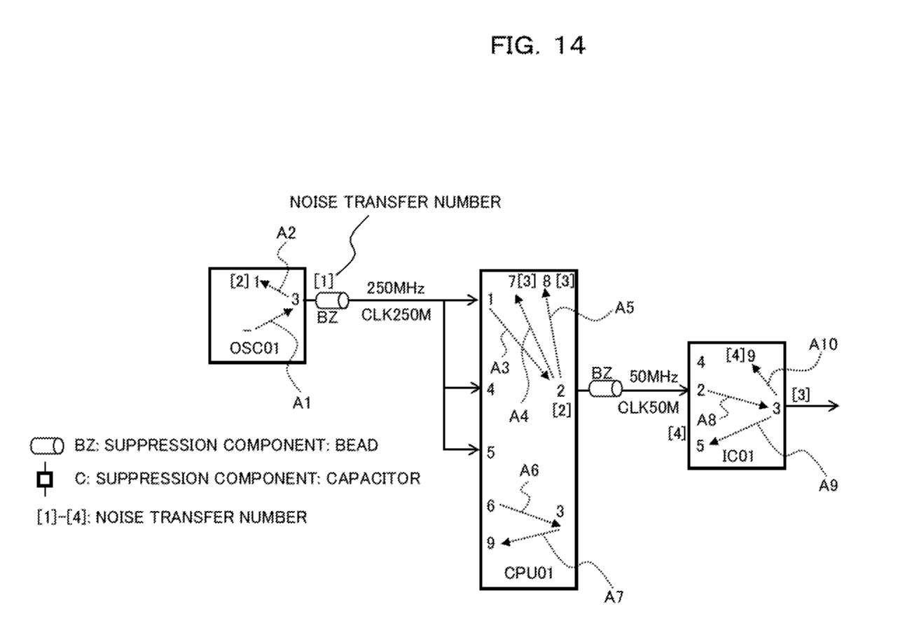

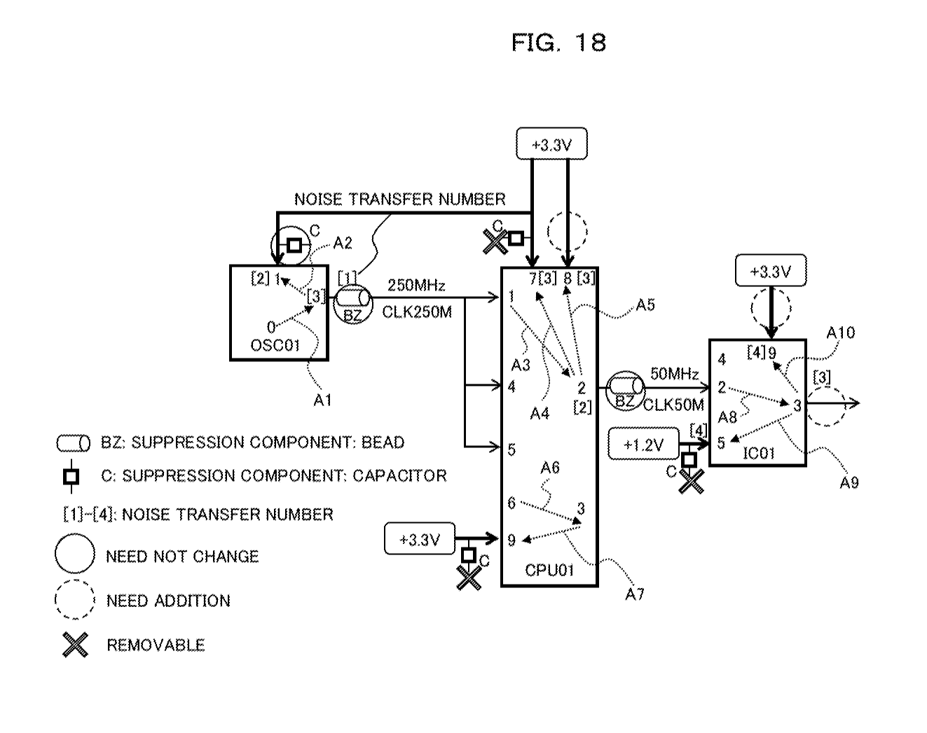

In the EMI transfer information library 32, only a noise transfer number corresponding to the pin number of a suppression candidate pin that is the source of the EMI noise is set to be “1” and the noise transfer numbers corresponding to the remaining suppression candidate pin numbers are each set to be “indefinite value”. The suppression candidate pin that is the source of the EMI noise is included in a component that generates EMI noise by itself and specifically in a clock pin of a clock generating source (oscillator). On the first row of the EMI transfer information library 32 of FIG. 3, only the noise transfer number corresponding to the clock pin (having suppression target pin number 3) of the component OSC01, which is the source (oscillator) of generating a clock, is set to be “1” while the noise transfer numbers in the second to tenth rows are set to be an “indefinite value”. As illustrated below with reference to FIGS. 14 and 18, numbers in squared brackets represent noise transfer numbers of the respective suppression candidate pins having pin numbers the same as those in the brackets.

The source pin number is a pin number that specifies the source pin that generates EMI noise that transfers to the suppression candidate pin having a corresponding suppression candidate pin number.

The pin having a suppression candidate pin number 3 and belonging to the component OSC01 is a pin that oscillates a clock, and no source pin generates EMI noise to be transferred to the pin having a suppression candidate pin number 3. For this reason, “−”, which means the absence, is set in the source pin number on the first row of the EMI transfer information library 32 of FIG. 3.

The source pin having a pin number 3 transfers the EMI noise to the pin having a suppression candidate pin number 1 and belonging to the component OSC01. Accordingly, “3” is set in the source pin number associated with the suppression candidate pin number “1” on the second row of the EMI transfer information library 32 of FIG. 3.

The source pin having a pin number 1 transfers the EMI noise to the pin having a suppression candidate pin number 2 and belonging to the component CPU01. Accordingly, “1” is set in the source pin number associated with the suppression candidate pin number “2” on the third row of the EMI transfer information library 32 of FIG. 3.

The source pin having a pin number 2 transfers the EMI noise to the pins having a suppression candidate pin numbers 7 and 8 and belonging to the component CPU01. Accordingly, “2” is set in the source pin numbers both associated with the suppression candidate pin numbers “7” and “8” on the fourth and fifth rows of the EMI transfer information library 32 of FIG. 3.

The source pins having pin numbers 6 and 3 transfer the EMI noise to the pins having suppression candidate pin numbers 3 and 9, respectively, and belonging to the component CPU01. Accordingly, “6” and “3” are set in the source pin numbers respectively associated with the suppression candidate pin numbers “3” and “9” on the sixth and seventh rows of the EMI transfer information library 32 of FIG. 3, respectively.

The source pin having a pin number 2 transfers the EMI noise to the pin having a suppression candidate pin number 3 and belonging to the component IC01. Accordingly, “2” is set in the source pin number associated with the suppression candidate pin number “3” on the eighth row of the EMI transfer information library 32 of FIG. 3.

The source pin having a pin number 3 transfers the EMI noise to the pins having suppression candidate pin numbers 5 and 9 and belonging to the component IC01. Accordingly, “3” is set in both the source pin numbers respectively associated with the suppression candidate pin numbers “5” and “9” on the ninth and tenth rows of the EMI transfer information library 32 of FIG. 3.

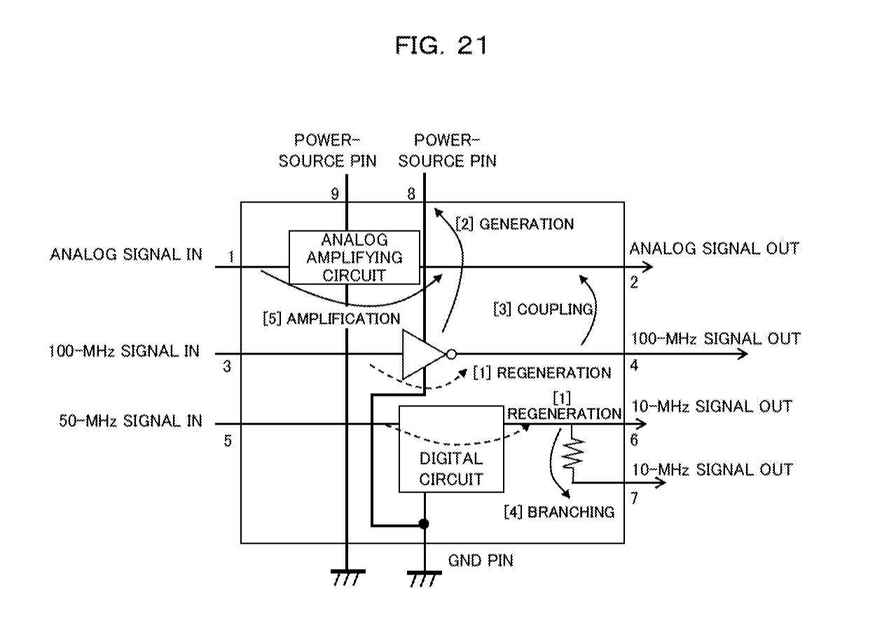

An EMI noise amount is determined in a manner that is to be detailed below with reference to FIG. 21 and corresponds to an amount of noise generated at a suppression candidate pin, which amount is determined on the basis of the type of transferring of the EMI noise from a source pin to the suppression candidate pin and a physical positional relationship between the source pin and the suppression candidate pin. Examples of the type of transferring EMI noise are regeneration, generation, coupling, branching, and amplification that are to be detailed with reference to FIG. 21. In the present embodiment, an EMI noise amount is determined, for example, to be a ratio (%) of an amount (noise voltage) of noise that is transferred to a suppression candidate pin and that is generated at the suppression candidate pin to an amount of noise generated at the source pin.

In the first and second rows of the EMI transfer information library 32 denoted in FIG. 3, 100% and 40% are respectively set in the EMI noise amounts of the suppression candidate pins (pin numbers 3 and 1) of the component OSC01.

In the third to seventh rows of the EMI transfer information library 32 denoted in FIG. 3, 100%, 10%, 40%, 100%, and 30% are respectively set in the EMI noise amounts of the suppression candidate pins (pin numbers 2, 7, 8, 3, and 9) of the component CPU01.

In the eighth to tenth rows of the EMI transfer information library 32 denoted in FIG. 3, 100%, 30%, and 40% are respectively set in the EMI noise amounts of the suppression candidate pins (pin numbers 3, 5 and 9) of the component IC01.

Here, the specific manners of generating the EMI transfer information library 32 and determining an EMI noise amount will be described below with reference to FIGS. 21-23.

The CAD design information 33 is design information of a board of the design target to be designed by means of a Computer Aided Design (CAD) system and includes pin coupling information related to the coupling relationship among multiple components on the board of the design target. For example, the CAD design information 33 related to the three components of OSC01, CPU01, and IC01 in the circuit diagram of FIG. 4 includes the following pieces (a1) to (a3) of the pin coupling information.

(a1) The clock pin (having a pin number 3) of the component OSC01 is coupled to the clock pins (having pin numbers 1, 4, and 5) of the component CPU01.

(a2) The clock pin (having a pin number 2) of the component CPU01 is coupled to the clock pin (having pin number 2) of the component IC01.

(a3) The power source is connected to the power-source pin (having pin number 1) of the component OSC01, the power-source pins (pin numbers 7, 8, and 9), of the CPU01, and the power-source pins (pin numbers 5 and 9) of the component IC01.

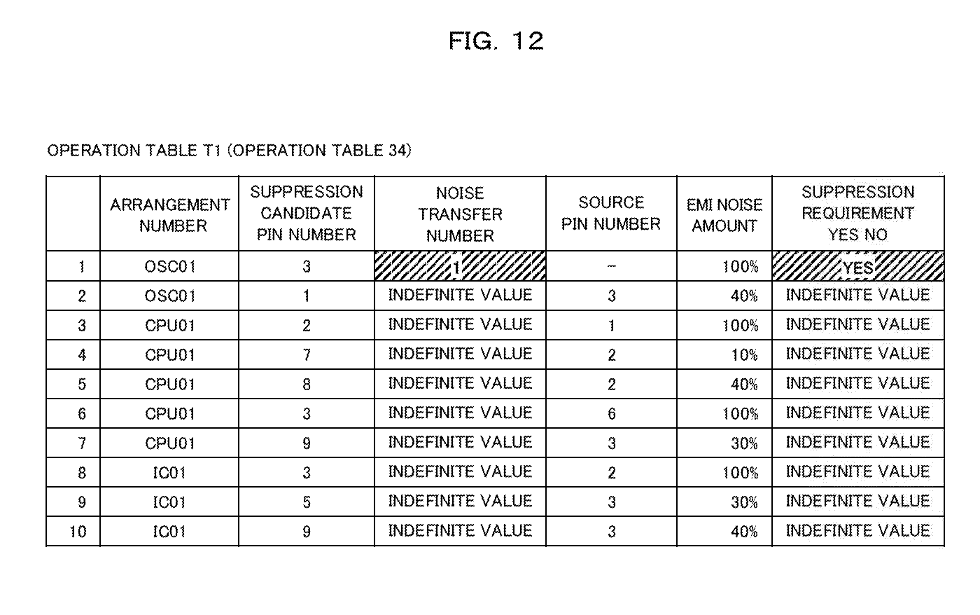

The operation table 34 is generated by expanding the EMI transfer information library 32 in a predetermined memory region on the memory 30, and is occasionally updated by a suppression target pin extractor 21 that is to be described below (see FIGS. 12, 13, and 15-17). In the operation table 34, a column “suppression requirement” in which a result of determination as to whether the corresponding suppression candidate pin needs arrangement of an EMI suppression component is set is added to the contents of the EMI transfer information library 32.

The input device 40 is, for example, the keyboard 15a and the mouse 15b illustrated in FIG. 2, and is operated by the user making various instructions for EMI suppression (design assist). The mouse 15b may be replaced with another pointing device, which is exemplified by a touch panel, a tablet terminal, a touch pad, or a trackball.

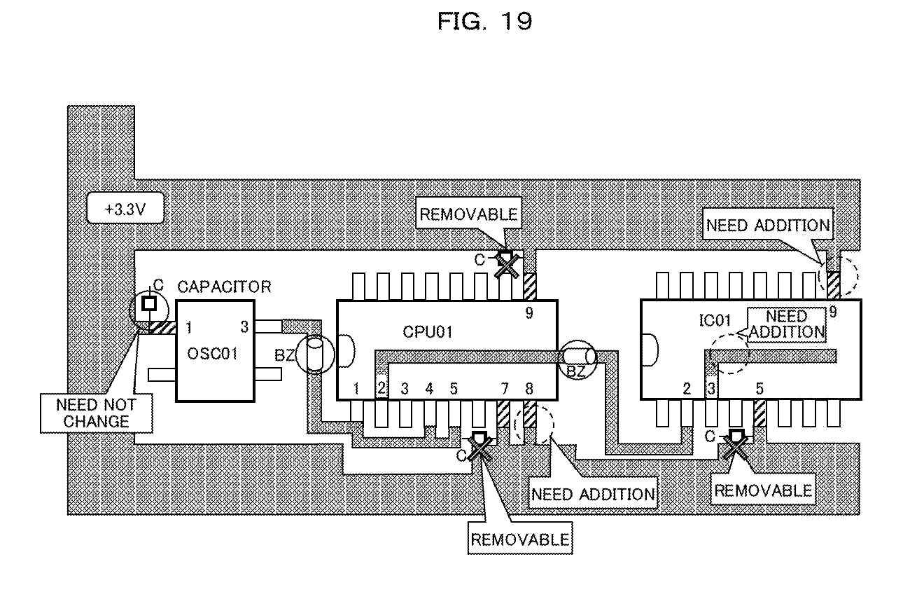

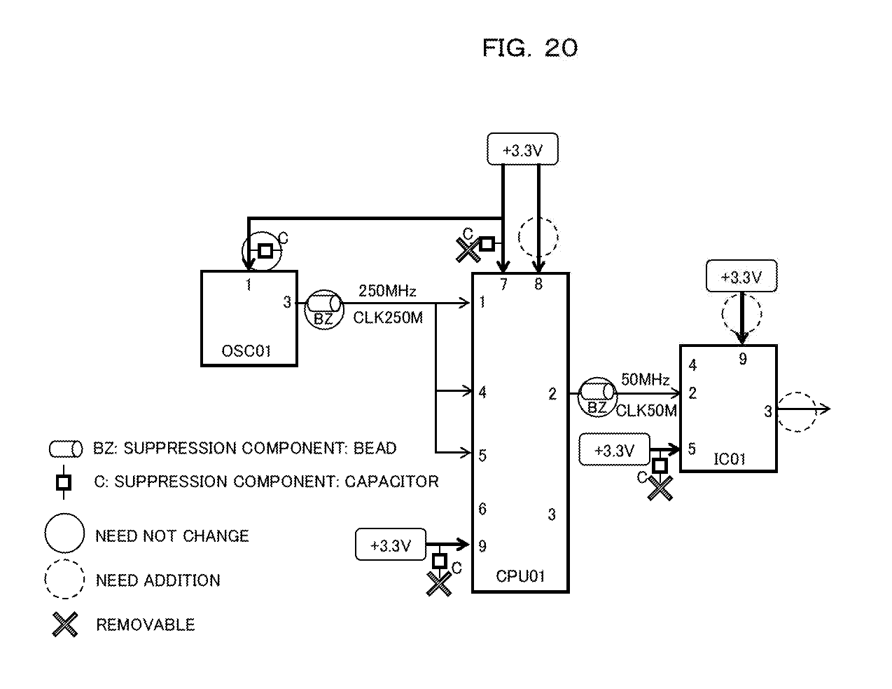

The display 50 is, for example, a monitor 14a illustrated in FIG. 2. The displaying state of the display 50 is controlled via the graphic processor 14 by a display controller 22 that is to be detailed below. The display 50 of the first embodiment outputs and displays a pattern diagram (see FIG. 19) and the system diagram of the power source and the clock (see FIGS. 18 and 20) that include information related to one or more suppression target pins.

Next, description will now be made in relation to the functions as the suppression target pin extractor 21 and the display controller 22 that are achieved by the processor 20 (processor 11).

The suppression target pin extractor 21 extracts a suppression candidate pin having an EMI noise amount equal to or more than a predetermined threshold (e.g., 40%) as a suppression target pin at which an EMI suppression component needs to be arranged on the basis of the above EMI transfer information library 32. Hereinafter, the EMI transfer information library 32 will sometimes be referred to simply as the library 32.

The display controller 22 controls the displaying state of the display 50 and thereby displays various pieces of information on the display 50 to present the information to the designer. In particular, the display controller 22 of the first embodiment controls the displaying state of the display 50 such that the pattern diagram (see FIG. 19) and the system diagram of a power source and a clock (see FIGS. 18 and 20) include information about the suppression target pin extracted by the suppression target pin extractor 21. This makes the designer possible to recognize the excess or shortage of an EMI suppression component at each pin by referring to the pattern diagram and system diagram of a power source and a clock displayed on the display 50.

Specifically, the suppression target pin extractor 21 and the display controller 22 exercise the following functions (b1)-(b4), (c1)-(c4), and (d1)-(d3).

(b1) The suppression target pin extractor 21 expands the library 32, as the operation table 34, into a predetermined memory region of the memory 30 and retrieves a first suppression candidate pin for which “1” is set in the noise transfer number from the operation table 34.

(b2) The suppression target pin extractor 21 determines whether the first noise amount (EMI noise amount) of the first suppression candidate pin retrieved by the function (b1) is equal to or more than the predetermined threshold.

(b3) If the first noise amount is equal to or more than the threshold as a result of the determination of the function (b2), the suppression target pin extractor 21 extracts the first suppression candidate pin as a suppression target pin and sets suppression requirement information indicating that the first suppression candidate pin needs EMI suppression in the suppression requirement column in the operation table 34 (see operation tables T1-T5 in FIGS. 12, 13, and 15-17). The display controller 22 controls the displaying state of the display 50 to output and display the suppression requirement information set for the first suppression candidate pin on the display 50.

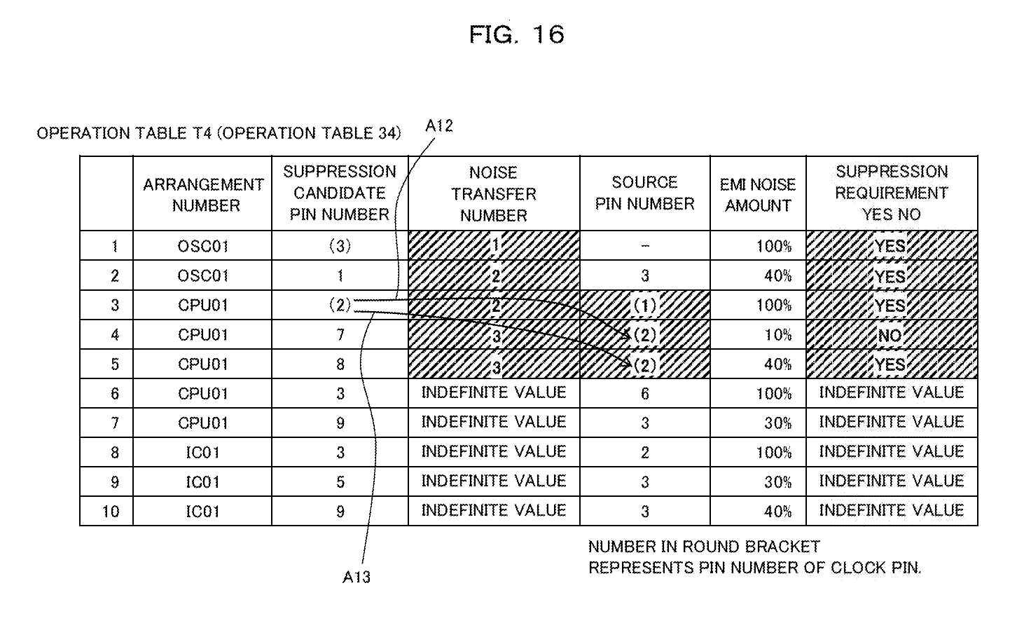

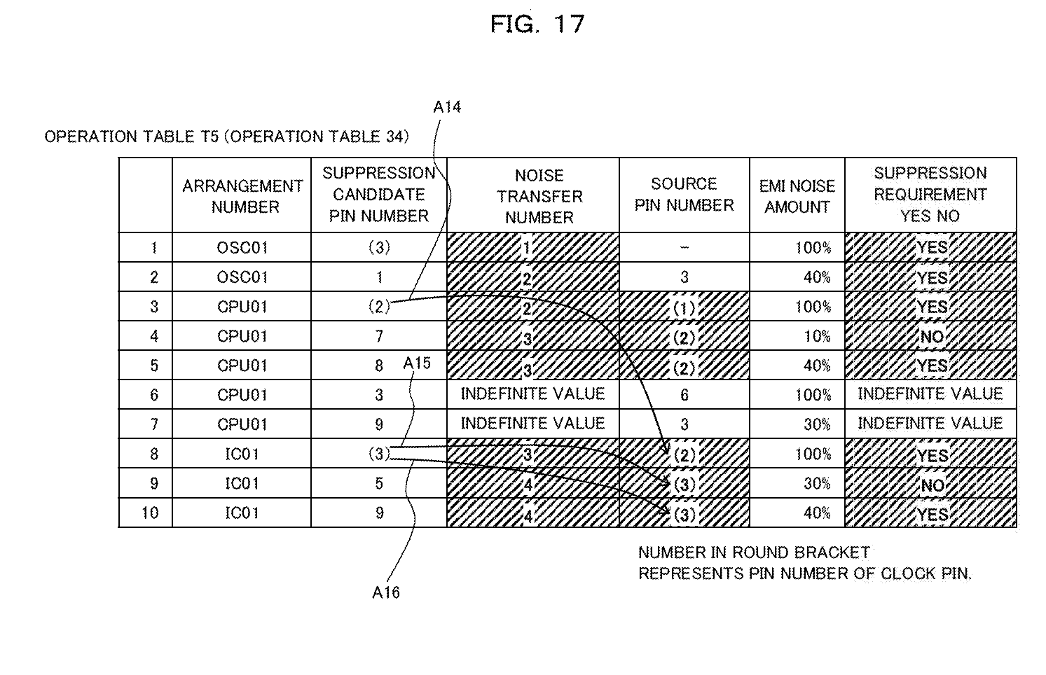

(b4) In contrast, if the first noise amount is less than the threshold as a result of the determination of the function (b2), the suppression target pin extractor 21 sets suppression non-requirement information indicating that the first suppression candidate pin does not need EMI suppression in the suppression requirement column in the operation table 34 (see operation tables T4 and T5 in FIGS. 16 and 17). The display controller 22 controls the displaying state of the display 50 to output and display the suppression non-requirement information set for the first suppression candidate pin on the display 50.

(c1) Then, the suppression target pin extractor 21 retrieves a following (i+1)-th suppression candidate pin from the operation table 34. Here, the symbol i represents an integer. An (i+1)-th suppression candidate pin is the suppression candidate pin associated as the source pin with an i-th suppression candidate pin in one of the plurality of components including the i-th suppression candidate pin, or the suppression candidate pin associated with the source pin coupled to the i-th suppression candidate pin in one of the plurality of components different from the component including the i-th suppression candidate pin. The latter (i+1)-th suppression candidate pin is retrieved from the operation table 34, using the pin coupling information in the above CAD design information 33. If the (i+1)-th suppression candidate pin is successfully retrieved, the processor 20 exercises the functions of the function (c2) and subsequent. On the other hand, if the (i+1)-th suppression candidate pin is not successfully retrieved, the processor 20 retrieves another first suppression candidate pin for which the noise transfer number is set to “1” from the operation table 34 and repeats the above function. In this retrieving, if another first suppression candidate pin is not retrieved, the processor 20 moves to the next process.

(c2) If the function (c1) successfully retrieves the (i+1)-th suppression candidate pin, the suppression target pin extractor 21 changes, in the operation table 34, the noise transfer number of the (i+1)-th suppression candidate pin from “indefinite value” to “i+1” and then determines whether the (i+1)-th noise amount at the (i+1)-th suppression candidate pin is equal to or more than the predetermined threshold.

(c3) If the (i+1)-th noise amount is equal to or more than the threshold as a result of the determination of the function (c2), the suppression target pin extractor 21 extracts the (i+1)-th suppression candidate pin as a suppression target pin and sets suppression requirement information indicating that the (i+1)-th suppression candidate pin needs EMI suppression in the suppression requirement column in the operation table 34. The display controller 22 controls the displaying state of the display 50 to output and display the suppression requirement information set for the (i+1)-th suppression candidate pin on the display 50.

(c4) In contrast, if the (i+1)-th noise amount is less than the threshold as a result of the determination of the function (c2), the suppression target pin extractor 21 sets suppression non-requirement information indicating that the (i+1)-th suppression candidate pin does not need EMI suppression in the suppression requirement column in the operation table 34. The display controller 22 controls the displaying state of the display 50 to output and display the suppression non-requirement information set for the (i+1)-th suppression candidate pin on the display 50.

(d1) When an EMI suppression component is already arranged at a suppression target pin extracted in the above manner, the display controller 22 controls the displaying state of the display 50 to output and display information representing that a change of the EMI suppression component is not needed (see the solid circles representing “need not change” in FIGS. 18-20) on the display 50.

When an EMI suppression component is not arranged at a suppression target pin extracted in the above manner, the display controller 22 controls the displaying state of the display 50 to output and display information representing that an addition of an EMI suppression component is needed (see the broken circles representing “need addition” in FIGS. 18-20) on the display 50.

(d3) When an EMI suppression component is arranged at a suppression candidate pin not extracted as a suppression target pin, the display controller 22 controls the displaying state of the display 50 to output and display information that the EMI suppression component needs deletion (see X marks representing “removable” in FIGS. 18-20) on the display 50.

### (5) Operation of an Information Processing Device Having the Design Assist Function of the First Embodiment

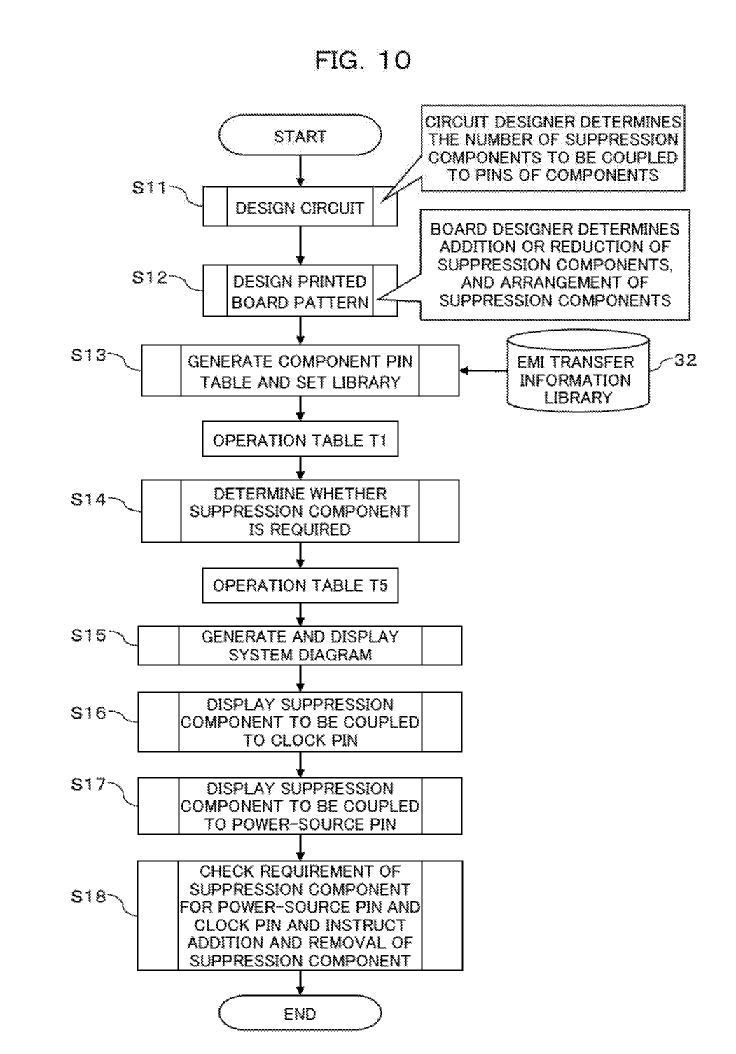

Next, description will now be made in relation to specific design assist and EMI suppression of the information processing device 10 of the first embodiment with reference to FIGS. 10-23.

### (5-1) Design Assist and EMI Suppression of the First Embodiment

First of all, description will now be made in relation to a procedure of arrangement design and displaying of an EMI suppression component of the first embodiment with reference to a flow diagram (steps S11-S18).

The circuit designer designs the circuit of the board of the design target with reference to the display 50 (step S11) and generates a circuit diagram illustrated, for example, FIG. 4. In this step, the circuit designer determines the number of EMI suppression components to be coupled to pins of the components arranged on the board of the design target.

As described above, the circuit diagram of FIG. 4 specifies that a bead BZ is coupled to each of the two clock pins; and four capacitors C are interposed in parallel between the power source (+3.3 V) and the ground. Although specifying the number of capacitors C, the circuit designer does not specify the arrangement positions of the capacitors C and in turn entrusts the arrangement positions to the pattern designer of the printed board.

Next, the pattern designer (board designer) of the printed board designs the pattern based on the circuit diagram generated by the circuit designer with reference to the display 50 (step S12) and consequently generates the pattern diagram illustrated in, for example, FIG. 5. In this step, the pattern designer examines addition or reduction of suppression components, and determines arrangement positions of the suppression components. The circuit designer may be the same as or different from the pattern designer.

After that, the suppression target pin extractor 21 of the information processing device 10 expands and sets the EMI transfer information library 32 already generated, as operation table 34 (see operation table T1 of FIG. 12), in a predetermined memory region of the memory 30 (step S13). In this step, the pin coupling information (component pin table) may also be generated on the basis of the CAD design information 33.

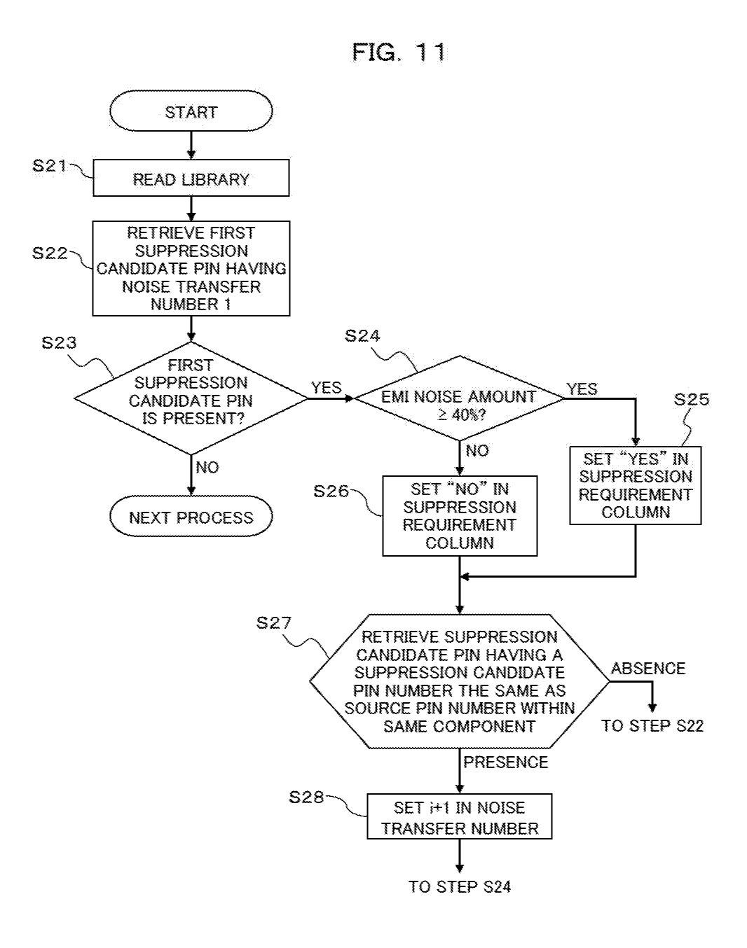

Then, the suppression target pin extractor 21 of the information processing device 10 determines whether an EMI suppression component is needed (step S14) and generates the operation table 34 (see table T5 in FIG. 17) including a result of determining whether each suppression candidate pin needs an EMI suppression component. A suppression candidate pin determined to need arrangement of an EMI suppression component is extracted as a suppression target pin. A detailed procedure of determination as to whether an EMI suppression component is needed in step S14 will be described below with reference to FIGS. 11-17.

Furthermore, with reference to the display 50, the circuit designer generates a system diagram of a power source and a clock illustrated in FIG. 7 on the basis of, for example, the pattern diagram of FIG. 5 designer by the pattern designer, and displays the generated system diagram (step S15).

As illustrated in, for example, FIG. 7, the system diagram thus generated displays thereon EMI suppression components (beads BZ) coupled to clock pins (step S16) and EMI suppression components (capacitors C) coupled to the power source pins (step S17).

The suppression target pin extractor 21 of the information processing device 10 refers to the operation table T5 and checks whether a power source pin and a clock pin (suppression candidate pins) of each component require suppression. Then, the suppression target pin extractor 21 instructs addition or removal of a suppression component on the basis of the result of the checking, and the display controller 22 controls the displaying state of the display 50 to output and display the instruction on the pattern diagram or the system diagram of a power source and a clock on the display 50 (step S18).

The instruction is carried out in the following steps (e1)-(e4) on the pattern diagram (see FIG. 19) or the system diagram (see FIGS. 18 and 20) of a power source and a clock.

(e1) When an EMI suppression component is not arranged for a suppression candidate pin which is determined to need suppression in the operation table T5 and which is extracted as a suppression target pin, a broken circle representing that addition of an EMI suppression component is need is displayed at a position that needs arrangement of an EMI suppression component.

(e2) When an EMI suppression component is arranged for a suppression candidate pin which is determined to need suppression in the operation table T5 and which is extracted as a suppression target pin, a solid circle representing that no change is needed (positive determination) is displayed at a position where the EMI suppression component is arranged.

(e3) When an EMI suppression component is arranged for a suppression candidate pin which is determined not to need suppression in the operation table T5, an X mark representing that the EMI suppression component needs to be removed (removal determination) is displayed at a position where the EMI suppression component is arranged.

(e4) When an EMI suppression component is not arranged for a suppression candidate pin which is determined not to need suppression in the operation table T5, particular indication is not displayed.

The circuit designer and the pattern designer can grasp excess or shortage of an EMI suppression component at each pin by referring to the above instruction and displaying on the pattern diagram and the system diagram of a power source and a clock.

### (5-2) Specific Procedure of Determining Whether an EMI Suppression Component is Needed in the First Embodiment

Next, description will now be made in relation to a specific procedure of determining whether an EMI suppression component is needed in the first embodiment by referring to FIGS. 11-17.

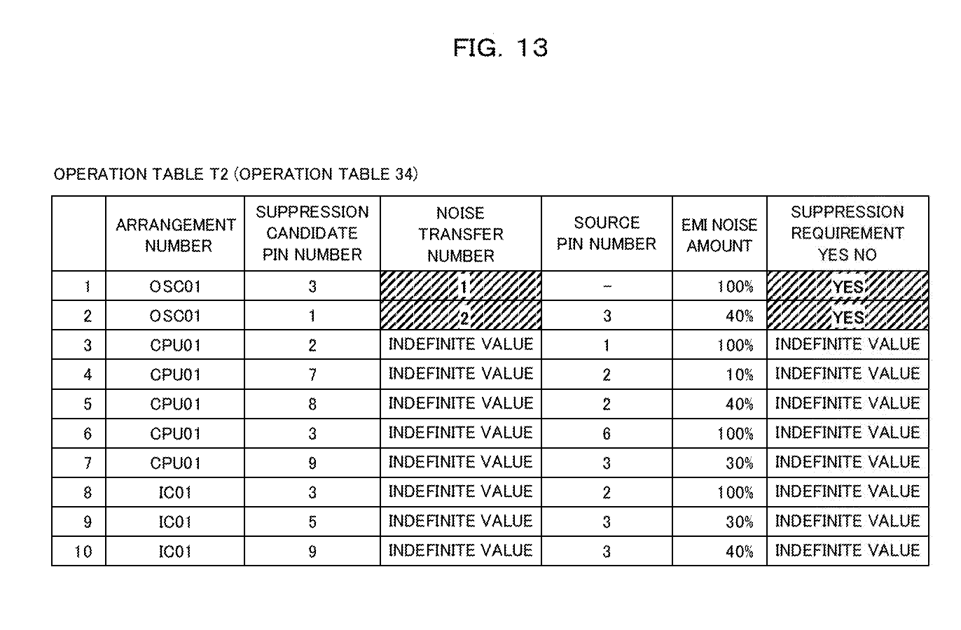

Here, the process of determining whether an EMI suppression component is needed in the first embodiment will now be described along a flow diagram (steps S21-S28) of FIG. 11 with reference to FIGS. 12 and 13. The process of the flow diagram of FIG. 11 is accomplished by using the above functions (b1)-(b4) and (C1)-(C4). In particular, the flow diagram of FIG. 11 determines whether each suppression candidate pin in a component containing a suppression candidate pin number associated with a noise transfer number 1 needs an EMI suppression component. FIGS. 12 and 13 are diagrams illustrating the contents of the operation tables T1 and T2 in determining whether an EMI suppression component is needed.

At the start of determination as to whether an EMI suppression component is needed, the suppression target pin extractor 21 first reads the EMI transfer information library 32 and generates the operation table 34 (step S21). The suppression target pin extractor 21 retrieves a suppression candidate pin (pin number of a first suppression candidate pin) for which a noise transfer number “1” is set from the operation table 34 (step S22), and determines whether a first suppression candidate pin is present (step S23).

If a first suppression candidate pin does not exist (NO route in step S23), the processor 20 moves to the next process. If a first suppression candidate pin exists (YES route in step S23), the suppression target pin extractor 21 determines whether the EMI noise amount of the first suppression candidate pin is equal to or more than a predetermined threshold 40% (step S24).

If the EMI noise amount is equal to or more than the predetermined threshold 40% (YES route in step S24), the suppression target pin extractor 21 extracts the first suppression candidate pin as a suppression target pin, and sets indication (YES) that the first suppression candidate pin needs EMI suppression in the suppression requirement column of the operation table 34 (step S25).

In contrast, if the EMI noise amount is determined to be less than the predetermined threshold 40% (NO route in step S24), the suppression target pin extractor 21 sets indication (NO) that the first suppression candidate pin does not need EMI suppression in the suppression requirement column of the operation table 34 (step S26).

After that, the suppression target pin extractor 21 retrieves, as an (i+1)-th suppression candidate pin (where i is an integer of one or more), a suppression candidate pin associated as the source pin with an i-th suppression candidate pin in the component containing the i-th suppression candidate pin from the operation table 34. This means that the suppression target pin extractor 21 retrieves, as the (i+1)-th suppression candidate pin, a suppression candidate pin having an i-th suppression candidate pin number the same as the source pin number in the same component from the operation table 34 (step S27).

If the (i+1)-th suppression candidate pin does not exist as the result of the retrieval (ABSENCE route in step S27), the suppression target pin extractor 21 returns to the process of steps S22 and S23. Specifically, if a first suppression candidate pin having a noise transfer number set to be “1” is present in the same or different component (YES route in step S23) as a result of the retrieval from the operation table 34 (step S22), the suppression target pin extractor 21 executes the process of above steps S24-28. If a first suppression candidate pin having a noise transfer number set to be “1” is absent both in the same and different components (NO route in step S23), the processor 20 moves to the next process.

If the (i+1)-th suppression candidate pin exists as a result of the retrieving in step S27 (PRESENCE route in step S27), the suppression target pin extractor 21 changes the noise transfer number of the (i+1)-th suppression candidate pin from “indefinite value” to “i+1” in the operation table 34 (step S28). After that, the suppression target pin extractor 21 carries out the process of above steps S24-S27 on the (i+1)-th suppression candidate pin.

Here, description will now be made in relation to a procedure of determining whether an EMI suppression component is needed when the EMI transfer information library 32 of FIG. 3 is applied to the flow diagram of FIG. 11 with reference to FIGS. 12 and 13.

The suppression target pin extractor 21 reads the EMI transfer information library 32 and generates an operation table T1 depicted in FIG. 12 (step S21). In the operation table T1 of FIG. 12, a suppression candidate pin having a pin number 3 and belonging to the component OSC01 is retrieved as a first suppression candidate pin because of having a noise transfer number “1” (step S22). Accordingly, a first suppression candidate pin having a noise transfer number set to be “1” is determined to exist (PRESENT route in step S23), and the suppression target pin extractor 21 determines whether the EMI noise amount of the first suppression candidate pin (having a pin number 3) is equal to or more than the predetermined threshold 40% (step S24).

The EMI noise amount of the first suppression candidate pin having a pin number 3 is 100% and therefore is determined to be equal to or more than 40% (YES route in step S24). Accordingly, the suppression target pin extractor 21 extracts the first suppression candidate pin (having a pin number 3) as the suppression target pin and, as denoted in FIG. 12, sets indication (YES) that the first suppression candidate pin (having a pin number 3) needs EMI suppression in the suppression requirement column of operation table T1 (step S25).

After that, the suppression target pin extractor 21 retrieves, as a second suppression candidate pin, a suppression candidate pin associated as the source pin with the first candidate pin within the same component that the first suppression candidate pin belongs to from the operation table T1. In the operation table T1 of FIG. 12, a suppression candidate pin (having a pin number 1) having a source pin number the same as the first suppression candidate pin number 3 within the same component OSC01 is retrieved as a second suppression candidate pin (PRESENT route in step S27).

Accordingly, as denoted in the operation table T2, the suppression target pin extractor 21 changes the noise transfer number of the second suppression candidate pin (having a pin number 1) from “indefinite value” to “1+1=2” (step S28). After that, the suppression target pin extractor 21 carries out the process of above steps S24-27 on the second suppression candidate pin (having a pin number 1).

Namely, the EMI noise amount of the second suppression candidate pin having a pin number 1 is 40%, which is determined to be equal to or more than the predetermined threshold 40% (YES route in step S24). Consequently, the suppression target pin extractor 21 extracts the second suppression candidate pin (having a pin number 1) as a suppression target pin and sets indication “YES” that the second suppression candidate pin (having a pin number 1) needs EMI suppression in the suppression requirement column of the operation table T2 as denoted in FIG. 13 (step S25).

After that, no suppression candidate pin (third suppression candidate pin) having a source pin number the same as the second suppression candidate pin number 1 within the same component OSC01 in the operation table T2 of FIG. 13 (ABSENCE route in step S27). In the operation table T2 of FIG. 13, a first suppression candidate pin having a noise transfer number “1” is absent from the same component OSC01 and other components CPU01 and IC01 (NO route in step S23). Consequently, the processor 20 moves to a process that will be detailed below with reference to FIGS. 14-17.

The suppression target pin extractor 21 carries out the following processes (f1)-(f7) on all the clock pin contained in each component having a noise generating source (i.e., pin having a noise transfer number “1”). Here, the processes (f1)-(f3) correspond to processes described above with reference to FIGS. 11-13.

(f1) the suppression target pin extractor 21 retrieves a first suppression candidate pin provided with a noise transfer number “1”.

(f2) The suppression target pin extractor 21 sets “i+1” in the noise transfer number of the (i+1)-th suppression candidate pin associated, as the source pin, with the i-th suppression candidate pin within the same component as the component that the i-th suppression candidate pin belongs to. The initial value of “i” is 1.

(f3) The suppression target pin extractor 21 determines whether the EMI noise amount of the (i+1)-th suppression candidate pin is equal to or more than the predetermined threshold 40%. If the EMI noise amount is equal to or more than the predetermined threshold 40%, the suppression target pin extractor 21 extracts the (i+1)-th suppression candidate pin as a suppression target pin, and sets indication (YES) that the (i+1)-th suppression candidate pin needs EMI suppression in the suppression requirement column associated with the (i+1)-th suppression candidate pin of the operation table 34. In contrast, if the EMI noise amount is less than the predetermined threshold 40%, the suppression target pin extractor 21 sets indication (NO) that the (i+1)-th suppression candidate pin does not need EMI suppression in the suppression requirement column of the operation table 34.

(f4) The suppression target pin extractor 21 sets “i+1” in the noise transfer number of the (i+1)-th suppression candidate pin associated with a source pin coupled to the i-th suppression candidate pin within a different component from the component that the i-th suppression candidate pin belongs to. The initial value of “i” is 1.

(f5) Likewise the process (f3), the suppression target pin extractor 21 determines whether the EMI noise amount of the (i+1)-th suppression candidate pin is equal to or more than the predetermined threshold 40%. If the EMI noise amount is equal to or more than the predetermined threshold 40%, the suppression target pin extractor 21 extracts the (i+1)-th suppression candidate pin as a suppression target pin, and sets indication (YES) that the (i+1)-th suppression candidate pin needs EMI suppression in the suppression requirement column associated with the (i+1)-th suppression candidate pin of the operation table 34. In contrast, if the EMI noise amount is less than the predetermined threshold 40%, the suppression target pin extractor 21 sets indication (NO) that the (i+1)-th suppression candidate pin does not need EMI suppression in the suppression requirement column associated with the (i+1)-th suppression candidate pin of the operation table 34.

(f6) The suppression target pin extractor 21 replaces “i” with “i+1” and repeats the above processes (f2)-(f5).

(f7) When a first suppression candidate pin having a noise transfer number “1” but having not been processed is present in the same or a different component, the suppression target pin extractor 21 carries out the processes (f1)-(f6) on the non-processed first suppression candidate pin.

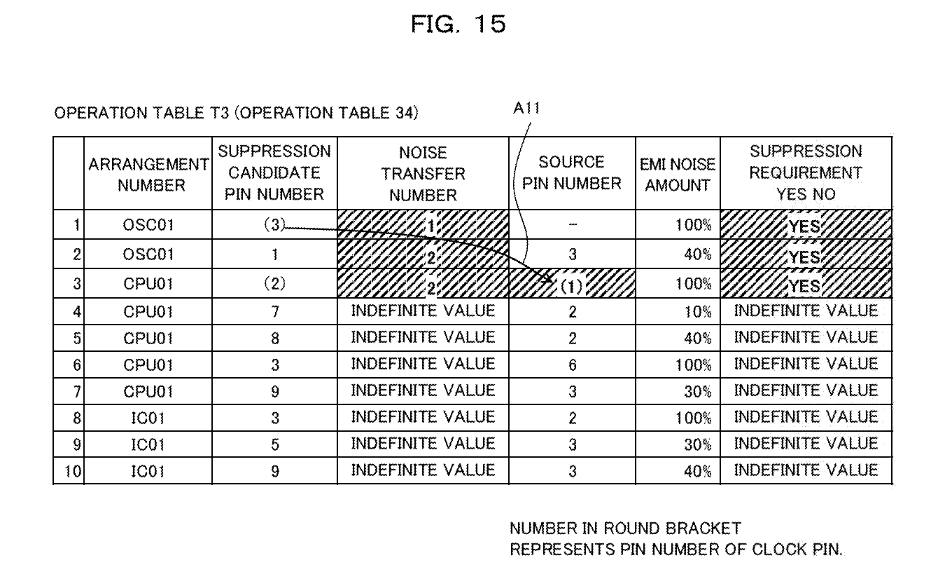

Next, the above processes (f1)-(f7) will be further detailed with reference to FIGS. 14-17. FIG. 14 is a diagram illustrating a procedure of providing a noise transfer number in the first embodiment; FIGS. 15-17 illustrate the operation tables T3-T5 when the requirement of an EMI suppression component is determined in the first embodiment. The numbers in squared brackets in FIG. 14 represent noise transfer numbers provided for respective suppression candidate pins attached thereto the numbers. The numbers in round brackets in FIGS. 15-17 represents the numbers of respective clock pins.

In FIG. 14, broken arrows A1-A10 correspond to associations (entries) of the first to tenth rows of the operation table 34 (T3-T5) of FIGS. 15-17.

In the process (f1), a first suppression candidate pin (having a pin number 3) provided with a noise transfer number “1” is retrieved in the component OSC01. After that, as denoted in the table T2 in FIG. 13, the process (f2) provides “1+1=2” to a noise transfer number of a second suppression candidate pin having a pin number 1 (see the broken arrow A2 of FIG. 14) associated, as the source pin, with the first suppression candidate pin having a pin number 3 in the same component OSC01. Since the first suppression candidate pin having a pin number 3 has an EMI noise amount 40%, which is equal to or more than the predetermined threshold 40%, the process (f3) sets indication (YES) that the suppression candidate pin having a pin number 1 needs EMI suppression in the suppression requirement column, as illustrated in the operation table T2 of FIG. 13.

The process (f4) provides “1+1=2” to a noise transfer number of a second suppression candidate pin (see broken arrow A3 in FIG. 14) having a pin number 2 and being associated with a source pin (having a pin number 1) coupled to the first suppression candidate pin having a pin number 3 in the component CPU01, which is different from the component OSC01 that the same first suppression candidate pin having a pin number 3 belongs to. At this time, the coupling relationship between the suppression candidate pin (having a pin number 3) in the component OSC01 and the source pin (having a pin number 1) in the component CPU01 is recognized on the basis of the pin coupling information (see FIG. 14 and arrow A11 in the operation table T3 in FIG. 15) described above. Since the EMI noise amount 100% of the second suppression candidate pin having a pin number 2 corresponds to being equal to or more than the predetermined threshold 40%, the process (f5) sets indication “YES” that the suppression candidate pin having a pin number 2 needs EMI suppression in the suppression requirement column associated with the suppression candidate pin number 2 of the operation table T3 in FIG. 15.

Furthermore, the process (f2) provides “2+1=3” to a noise transfer number of the third suppression candidate pins having pin numbers 7 and 8 associated as a source pin with the second suppression candidate pin having a pin number 2 in the same component OSC01 as the component containing the second suppression candidate pin having a pin number 2 (see broken arrows A4 and A5 of FIG. 14 and arrows A12 and A13 of the operation table T4 of FIG. 16). Since the EMI noise amount 10% of the third suppression candidate pin having a pin number 7 is less than the predetermined threshold 40%, the process (f3) sets indication “NO” that the suppression candidate pin having a pin number 7 does not need EMI suppression in the suppression requirement column associated with the suppression candidate pin number 7 of the operation table T4 in FIG. 16. In contrast, since the EMI noise amount 40% of the second suppression candidate pin having a pin number 8 corresponds to being equal to or more than the predetermined threshold 40%, the process (f3) sets indication “YES” that the suppression candidate pin having a pin number 8 needs EMI suppression in the suppression requirement column associated with the suppression candidate pin number 8 of the operation table T4 in FIG. 16.

The process (f4) provides “2+1=3” to a noise transfer number of a third suppression candidate pin (see broken arrow A8 in FIG. 14) having a pin number 3 and being associated with a source pin (having a pin number 2) coupled to the second suppression candidate pin having a pin number 2 in the component IC01, which is different from the component CPU01 that the same second suppression candidate pin having a pin number 2 belongs to. At this time, the coupling relationship between the suppression candidate pin (having a pin number 2) in the component CPU01 and the source pin (having a pin number 2) in the component IC01 is recognized on the basis of the pin coupling information (see FIG. 14 and arrow A14 in the operation table T5 in FIG. 17) described above. Since the EMI noise amount 100% of the third suppression candidate pin having a pin number 3 corresponds to being equal to or more than the predetermined threshold 40%, the process (f5) sets indication “YES” that the suppression candidate pin having a pin number 3 needs EMI suppression in the suppression requirement column associated with the suppression candidate pin number 3 of the operation table T5 in FIG. 17.

Furthermore, the process (f2) provides “2+1=3” to a noise transfer number of the fourth suppression candidate pins having pin numbers 5 and 9 associated as a source pin with the third suppression candidate pin having a pin number 3 in the same component IC01 as the component containing the third suppression candidate pin having a pin number 3 (see broken arrows A9 and A10 of FIG. 14 and arrows A15 and A16 of the operation table T5 in FIG. 17). Since the EMI noise amount 30% of the fourth suppression candidate pin having a pin number 5 is less than the predetermined threshold 40%, the process (f3) sets indication “NO” that the suppression candidate pin having a pin number 5 does not need EMI suppression in the suppression requirement column associated with the suppression candidate pin number 5 of the operation table T5 in FIG. 17. In contrast, since the EMI noise amount 40% of the fourth suppression candidate pin having a pin number 9 corresponds to being equal to or more than the predetermined threshold 40%, the process (f3) sets indication “YES” that the suppression candidate pin having a pin number 9 needs EMI suppression in the suppression requirement column associated with the suppression candidate pin number 9 of the operation table T5 in FIG. 17.

As illustrated in the operation table T5 in FIG. 17, the noise transfer numbers mean the order of coupling components and therefore each noise transfer number of 2 or more is determined while the operation table is being generated. In the first embodiment, a suppression candidate pin having an EMI noise amount equal to or more than 40% and also having a noise transfer number of 1 or more is extracted as a suppression target pin at which an EMI suppression component needs to be arranged. In addition, the noise transfer number and the suppression requirement of a suppression candidate pin number that are not used and are disconnected from the circuit are both set to be “indefinite value”. A noise transfer number represents presence or absence of EMI noise at the corresponding suppression candidate pin. Specifically, a noise transfer number set to be an integer of 1 or more can be understood as the presence of EMI noise at the corresponding suppression candidate pin while a noise transfer number set to be an indefinite value can be understood as the absence of EMI noise at the corresponding suppression candidate pin.

Then, as described above, the suppression target pin extractor 21 of the information processing device 10 checks the suppression requirement of the power-source pin and the clock pin (suppression candidate pin) of each component with reference to the operation table T5. After that, the suppression target pin extractor 21 instructs, for example, addition or removal of an EMI suppression component on the basis of the result of the checking, and the display controller 22 controls the displaying state of the display 50 to output and display the above instruction on the pattern diagram or the system diagram of the power source and the clock (see step S18 of FIG. 10).

The instruction is displayed on the pattern diagram as illustrated in FIG. 19. FIG. 19 is an example of a pattern diagram of the board of the design target of the first embodiment, the pattern diagram being designed and displayed from the circuit diagram of FIG. 4. In particular, the pattern diagram of FIG. 19 illustrates a state where instructions along the above steps (e1)-(e4) on the basis of the operation table T5 are displayed on the pattern diagram of FIG. 5.

The instructions are displayed on the system diagram of a power source and a clock as illustrated in FIG. 20. FIG. 20 is an example of the system diagram of a power source and a clock of the board of the design target of the first embodiment, the system diagram being generated and displayed from the pattern diagram of FIG. 19. In particular, the system diagram of a power source and a clock of FIG. 20 illustrates a state where instructions along the above steps (e1)-(e4) on the basis of the operation table T5 are displayed on the system diagram of a power source and a clock of FIGS. 7 and 8.

FIG. 18 illustrates an example of a system diagram of a power source and a clock of the board of the design target of the first embodiment, the system diagram being generated on the basis of the operation table T5 of FIG. 17, along with the noise transfer directions (Arrows A1-A10) and the noise transfer numbers (numbers in squared brackets). This means that, the system diagram of a power source and a clock of FIG. 18 illustrates a state where the instruction based on the operation table T5 is displayed on the system diagram of a power source and a clock of FIGS. 7 and 8, along with the noise transfer directions (Arrows A1-A10) and noise transfer numbers (numbers in squared brackets) based on the operation table T5.

As illustrated in FIGS. 18-20, the display 50 displays thereon the following instructions in accordance with the above steps (e1)-(e4).

The suppression candidate pin numbers 3 and 1 of the component OSC01 are provided with noise transfer number 1 and 2, respectively, and are both set to be “YES” in the suppression requirement. In addition, a bead BZ and the capacitor C, which are EMI suppression components, are already arranged at the suppression candidate pins having pin numbers 3 and 1, respectively. For the above, solid circles representing not needing change (positive determination) are displayed at the positions where the EMI suppression components are arranged in accordance with the step (e2).

The suppression candidate pin number 2 of the component CPU01 is provided with a noise transfer number 2 and is set to be “YES” in the suppression requirement. In addition, a bead BZ, which is an EMI suppression component, is already arranged at the suppression candidate pin having a pin number 2. For the above, a solid circle representing not needing change (positive determination) is displayed at the position where the EMI suppression component is arranged in accordance with the step (e2).

The suppression candidate pin number 8 of the component CPU01 is provided with a noise transfer number 3 and is set to be “YES” in the suppression requirement. However, no EMI suppression component is arranged at the suppression candidate pin having a pin number 8. For the above, a broken circle representing needing addition of an EMI suppression component is displayed at the position where the EMI suppression component needs to be arranged in accordance with the step (e1).

The suppression candidate pin number 7 of the component CPU01 is provided with a noise transfer number 3 and is set to be “NO” in the suppression requirement. However, an EMI suppression component is already arranged at the suppression candidate pin having a pin number 7. For the above, a negative mark (X) representing needing removal (removal determination) is displayed at the position where the EMI suppression component is arranged in accordance with the step (e3).

The suppression candidate pin number 9 of the component CPU01 is not provided with a noise transfer number and is set to be “indefinite value” in the suppression requirement, which means that the suppression candidate pin having a pin number 9 is unused. However, an EMI suppression component is already arranged at the suppression candidate pin having a pin number 9. For the above, a negative mark (X) representing needing removal (removal determination) is displayed at the position where the EMI suppression component is arranged in accordance with the step (e3).

The suppression candidate pin numbers 3 and 9 of the component IC01 are provided with noise transfer numbers 3 and 4, respectively, and both are set to be “YES” in the suppression requirement. However, no EMI suppression component is arranged at the suppression candidate pins having pin numbers 3 and 9. For the above, broken circles representing needing addition of EMI suppression components is displayed at the positions where the EMI suppression components need to be arranged in accordance with the step (e1).

The suppression candidate pin number 5 of the component IC01 is provided with a noise transfer number 4 and is set to be “NO” in the suppression requirement. However, an EMI suppression component is already arranged at the suppression candidate pin having a pin number 5. For the above, a negative mark (X) representing needing removal (removal determination) is displayed at the position where the EMI suppression component is arranged in accordance with the step (e3).

### (5-3) Procedure of Generating an EMI Transfer Information Library of the First Embodiment

Next, description will now be made in relation to a procedure of generating the EMI transfer information library 32 of the first embodiment with reference to FIGS. 21-23.

The present invention assumes a case where, between two pins A and B in the same component, EMI noise is generated at one pin A and the noise generation further generates EMI noise having the same frequency component as the noise at pin A at the other pin B. In this case, pin A that is the cause of generation of the EMI noise is called the “source pin” while pin B that can be a target of arranging an EMI suppression component is called a “suppression candidate pin”.

As described above, the EMI noise amount generated at a “suppression candidate pin” is represented in a ratio (%) of noise transferred to and generated at the suppression candidate pin with respect to the amount of noise generated at the source pin. The EMI noise amount is calculated on the basis of a coupling state (i.e., the following types (1)-(5) of transferring to be detailed below) related to EMI radiation between the “suppression candidate pin” and a “source pin” as will be detailed below.

In the first embodiment, the EMI transfer information library 32 (see FIG. 3), in which information associating a “suppression candidate pin number”, a “noise transfer number”, a “source pin number”, and an “EMI noise amount” of each individual component with one another is converted into a library, is generated in the following manner. Specifically, the EMI transfer information library 32 is generated on the basis of the state of circuit coupling between the source pin and the suppression candidate pin (intra-circuit coupling) and the states of physical arrangement of pins in the component. Alternatively, the EMI transfer information library 32 may be generated on the basis of the results of experiments and analysis performed on each individual component.

The above EMI transfer information library 32 is generated by the following steps (g1)-(g3). For example, the EMI transfer information library 32 may be generated by the computer 10 executing a predetermined application program in the following procedural steps (g1)-(g3). The steps (g1)-(g3) are carried out for each component to be arranged on the board of the design target.

(g1) Two pins between which EMI noise transfers within the same component are specified and classified into the suppression candidate pin and the source pin.

(g2) The EMI noise amount (%) generated at the suppression candidate pin is calculated and determined on the basis of the corresponding one of the types [1]-[5] of transferring noise from the source pin to the suppression candidate pin and the physical arrangement relationship of the two pins.

(g3) A suppression candidate pin number and the source pin number that specify the suppression candidate pin and the source pin obtained in step (g1), respectively, a noise transfer number of the suppression candidate pin number, and the EMI noise amount (%) obtained in step (g2) are registered in the EMI transfer information library 32 in association with one another. At this time, only the noise transfer number corresponding to the pin number of a suppression candidate pin that is the source of generating EMI noise is set to “1” while the noise transfer numbers of the remaining suppression candidate pin numbers are set to “indefinite value”.

Here, description will now be made in relation to the types [1]-[5] of transferring EMI noise and a procedure of calculating EMI noise amount for each type of transferring with reference to FIGS. 21-23. The types [1]-[5] of transferring EMI noise represent the following mechanisms of transferring EMI noise.

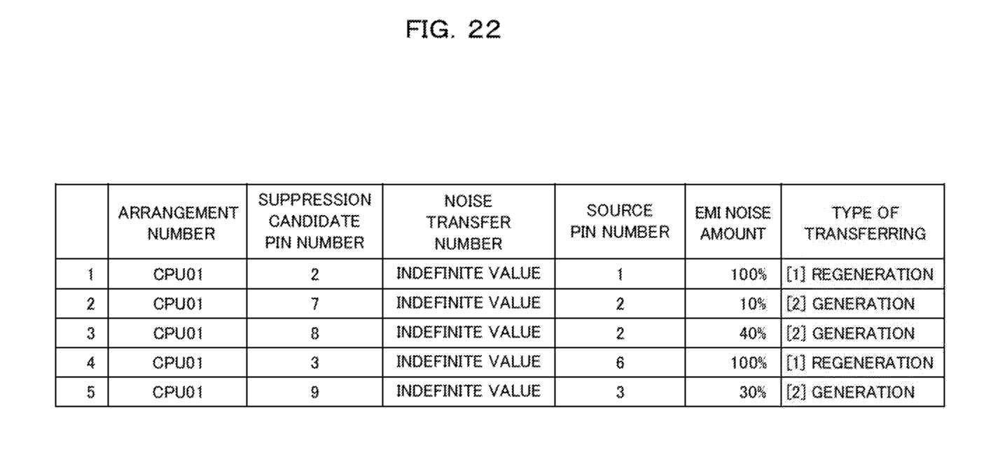

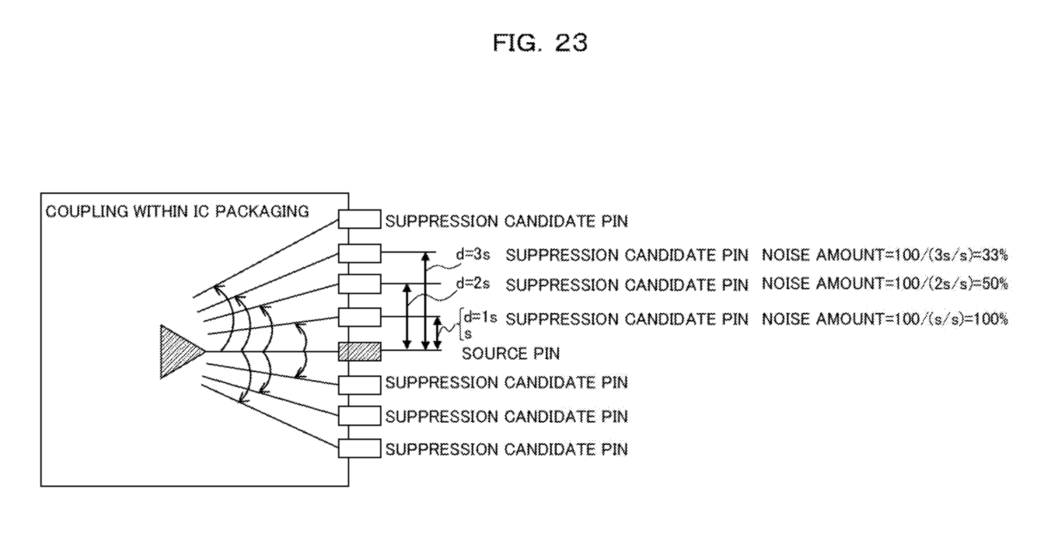

FIG. 21 is a diagram illustrating the types [1]-[5] of transferring EMI noise and a procedure of calculating an EMI noise amount for each type of transferring EMI noise. FIG. 22 is a diagram illustrating an example of generating the EMI transfer information library 32 of FIG. 3 and the types [1] and [2] of transferring EMI noise in association with each other. FIG. 23 is a diagram illustrating a procedure of calculating an EMI noise amount of noise that transfers from a source pin to a suppression candidate pin by coupling.

The component illustrated in FIG. 21 includes nine pins, which are numbered from 1 to 9 to specify the respective pins. The pin having a pin number 1 is an analog signal input pin and the pin having a pin number 2 is an analog signal output pin. An analog amplifying circuit is interposed between the pin having a pin number 1 and the pin having a pin number 2. The pin having a pin number 3 is a 100-MHz signal input pin and the pin having a pin number 4 is a 100 MHz-signal output pin. A cross buffer is interposed between the pin having a pin number 3 and the pin having a pin number 4. The pin having a pin number 5 is a 50-MHz signal input pin and the pin having a pin number 6 is a 10 MHz signal output pin. A digital circuit is interposed between the pin having a pin number 5 and the pin having a pin number 6. The pin having a pin number 7 is a 10-MHz signal output pin and is branched from the pin having a pin number 6. The pins having pin numbers 8 and 9 are power source pins coupled to ground pins (GND pins).

The type [1] of transferring EMI noise is “regeneration”, which is exemplified by logical transfer of EMI noise from an input pin to an output pin in a digital IC. For example, the transfer from the source pin number 3 to the suppression candidate pin number 4 and the transfer from the source pin number 5 to the suppression candidate pin number 6 correspond to “regeneration” in FIG. 21. In another example of FIG. 22, the transfer from the source pin number 1 to the suppression candidate pin number 2 in the component CPU01 and the transfer from the source pin number 6 to the suppression candidate pin number 3 in the component CPU01 correspond to “regeneration”. The output pins of, for example, a clock buffer, a digital circuit, and an oscillator (OSC) each include a driver circuit and generate 100% EMI noise. Therefore, if the type of transferring EMI noise is [1] regeneration, the EMI noise amounts at the suppression candidate pin numbers 4 and 6 are unconditionally determined to be 100%.

The type [2] of transferring EMI noise is “generation”, which is exemplified by EMI noise generated at a power source pin of a clock output circuit. For example, the transfer from the source pin number 4 to the suppression candidate pin number 8 in FIG. 21 corresponds to “generation”. In another example of FIG. 22, the transfer from the source pin number 2 to the suppression candidate pin number 7 in the component CPU01, the transfer from the source pin number 2 to the suppression candidate pin number 8 in the component CPU01, and the transfer from the source pin number 3 to the suppression candidate pin number 9 in the component CPU01 correspond to “generation”. The EMI noise amount by “generation” indicates an intensity of noise generation by electrical coupling and is represented by the numerical value of 1-99%. The EMI noise amount by “generation” can be expressed by a ratio of noise voltage at a suppression candidate pin to that of a source pin, the noise voltages being obtained through actual voltage measurement or voltage analysis. For example, in states where the source pin has a noise voltage of 1 V and the suppression candidate pin has a noise voltage of 0.4 V (e.g., at 100 MHz), the EMI noise amount by “generation” is determined to be 40% (0.4/1×100=40%).

The type [3] of transferring EMI noise is “coupling”, which corresponds to transferring of EMI noise from the generating pin (source pin) of EMI noise to an adjacent pin (suppression candidate pin) by, for example, electromagnetic coupling. For example, the transfer from the source pin number 4 to the suppression candidate pin number 2 in FIG. 21 corresponds to “coupling”. An EMI noise amount by “coupling” indicates an intensity of spatial electromagnetic coupling and is represented by a numerical value of 1-99% determined in terms of physical arrangement and distance of two pins. For example, an EMI noise amount by “coupling” can be determined by each of the following three methods (h1)-(h3).

(h1) Firstly, an “S” parameter between two pins is analyzed and an obtained S21 attenuation rate is determined to be an EMI noise amount by “coupling”. For example, if the S21 attenuation rate is 0.5 (e.g., at 100 MHz), the EMI noise amount by “coupling” is determined to be 50%.

(h2) Likewise the above “generation”, the EMI noise amount by “coupling” can be expressed by a ratio of noise voltage at a suppression candidate pin to that of a source pin, the noise voltages being obtained through actual voltage measurement or voltage analysis. For example, in states where the source pin has a noise voltage of 1 V and the suppression candidate pin has a noise voltage of 0.4 V (e.g., at 100 MHz), the EMI noise amount by “coupling” is determined to be 40% (0.4/1×100=40%).

(h3) An EMI noise amount by “coupling” is calculated on the basis of the physical arrangement (distance) between two pins as illustrated in FIG. 23. The example of FIG. 23 assumes that the pins that can be source pins or suppression candidate pins are arranged at regular intervals s (mm), the distance between a source pin and a suppression candidate pin is d (mm), and the distance between a source pin and a contiguous pin (closest pin) to the source pin is s (mm). The EMI noise amount (level) by “coupling” is determined to be 100/(d/s) %. In other words, in the example of FIG. 23, the EMI noise amount when d=1 s is calculated to be 100%; the EMI noise amount when d=2 s is calculated to be 50%; and the EMI noise amount when d=3 s is calculated to be 33%.

The type [4] of transferring EMI noise is “branching”, which corresponds to a case where an EMI noise having the same frequency is branched from a pin to transfer to a destination pin which is coupled to the pin. In the example of FIG. 21, the transfer from the source pin number 6 to the suppression candidate pin number 7 corresponds to “branching”. The EMI noise amount by “branching” takes a value of 1-99% determined in terms of a branching state of the circuit in a component. For example, an output from a clock corresponds to an EMI noise generated at the branched destination pin, to which the EMI noise is distributed, and the EMI noise generated at the branched destination pin is nearly 100%. The level of an EMI noise amount by “branching” is nearly the same as the EMI noise amount by “regeneration”, but is determined to be 99% in order to be discriminated from an EMI noise amount by “regeneration”.

The type [5] of transferring EMI noise is “amplification”, which corresponds to transfer of amplified EMI noise from the output pin of an analog amplifying circuit to the output pin of the same circuit. In the example of FIG. 21, the transfer from the source pin number 1 to the suppression candidate pin number 2 corresponds to “amplification”. In this case, the amplification generates n times noise according to the amplifying factor n of the analog amplifying circuit. When the amplifying factor is two, the EMI noise by “amplification” is determined to be 200%.

### (6) Result of the First Embodiment

In the first embodiment described the above, designers such as a circuit designer and a pattern designer can grasp excess or shortage of an EMI suppression component on each pin simply by referring to a pattern diagram or a system diagram of a power source and a clock (output and displayed) on the screen of the display 50. This can display an unnecessary EMI suppression component and a component pin that needs arrangement of EMI suppression component, which allows an underskilled designer to accomplish an optimum arrangement by arranging each EMI suppression component for a proper pin. Accordingly, high-quality circuit design can be achieved by taking a measure to suppress EMI noise irrespective of the skill of the designer, and occurrence of an EMI problem can be avoided. In addition, an unnecessary EMI suppression component can be prohibited from being arranged.

Furthermore, the designer confirms the presence or absence of EMI noise at each suppression candidate pin simply by referring to a noise transfer number associated with the suppression candidate pin in the operation table 34. In addition, the designer exactly confirms the sequential order of coupling components, that is, the sequential order of arrangement, by referring to the noise transfer number in the operation table 34 when designing and generating a pattern diagram and a system diagram. This allows higher-quality design to be realized.

### (7) Others

A preferred embodiment of the present invention is described above, but the present invention is not limited to the foregoing embodiment. Various changes and modifications can be suggested without departing from the spirit of the present invention.

For example, the first embodiment assumes that the output device that outputs information about a suppression target pin is the display 50 such as a monitor 14a that displays and outputs the information. The output device of the present invention is not limited to this. Alternatively, the output device may be a printer that prints and outputs the information. A printer serving as the output device brings the same advantages as those of the first embodiment.

In the above first embodiment, the predetermined threshold serving as the basis to extract a suppression candidate pin as a suppression target pin is assumed to be 40%. However, the present invention is not limited to this. Besides, an EMI noise amount at a suppression candidate pin is expressed relative value (i.e., the ratio of a noise amount at a suppression candidate pin to the noise amount at the corresponding source pin), but the present invention is not limited to this. Alternatively, a noise voltage or other value at a suppression candidate pin may be used as an EMI noise amount.

The measure to suppress electromagnetic noise can be taken regardless of the skill of the designer.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present inventions have been described in detail, it should be understood that the various changes, substitutions, and alterations could be made hereto without departing from the spirit and scope of the invention.

What is claimed is:

1. A non-transitory computer-readable recording medium having stored therein a design assist program that assists in arrangement design of a suppression component to suppress electromagnetic noise and to be disposed on a board when the board is designed by arranging a plurality of components thereon, the design assist program causing a computer to execute a process comprising:
extracting, based on an association among a source pin that is a source of generating the electromagnetic noise, a suppression candidate pin on which a measure against the electromagnetic noise generated by the source pin is to be taken, and a noise amount of noise that acts on the suppression candidate pin and that is originated from the electromagnetic noise generated at the source pin, the association being obtained for each of the plurality of components, a suppression candidate pin having a noise amount equal to or larger than a predetermined value as a suppression target pin for which the suppression component is to be arranged from a plurality of the suppression candidate pins; and
outputting, from an output device, information about the suppression target pin extracted.

2. The non-transitory computer-readable recording medium according to claim 1, wherein:
the association is in a form of a library;
the library is generated by, for each of the plurality of components,
specifying two pins in the component through which the electromagnetic noise transfers as the source pin and the suppression candidate pin,
determining the noise amount on the suppression candidate pin by referring to a type of transferring of the electromagnetic noise from the source pin to the suppression candidate pin and physical positional relationship between the source pin and the suppression candidate pin, and
associating the specified source pin and the specified suppression candidate pin and the determined noise amount with one another.

3. The non-transitory computer-readable recording medium according to claim 2, wherein:
the library includes a noise transfer number that represents an order of transferring of the electromagnetic noise for each of the plurality of suppression candidate pins; and
in generating the library, a noise transfer number “1” is set for a suppression candidate pin corresponding to an output pin of a component that generates the electromagnetic noise and a noise transfer number “indefinite value” is set for the remaining suppression candidate pins.

4. The non-transitory computer-readable recording medium according to claim 3, the process further comprising:
expanding the library, as an operation table, into a predetermined memory region;
retrieving a first suppression candidate pin having the noise transfer number being “1” from the operation table;
determining whether a first noise amount on the first suppression candidate pin retrieved is equal to or larger than the predetermined value;
when the first noise amount is equal to or larger than the predetermined value, extracting the first suppression candidate pin as the suppression target pin, setting suppression requirement information representing that suppression on the first suppression candidate pin is required in the operation table, and outputting the suppression requirement information from the outputting device; and
when the first noise amount is smaller than the predetermined value, setting suppression non-requirement information representing that suppression on the first suppression candidate pin is not required in the operation table, and outputting the suppression non-requirement information from the outputting device.

5. The non-transitory computer-readable recording medium according to claim 4, the process further comprising:
retrieving, as an (i+1)-th suppression candidate pin (where i is an integer of one or more), the suppression candidate pin associated as the source pin with an i-th suppression candidate pin in one of the plurality of components including the i-th suppression candidate pin or the suppression candidate pin associated with the source pin coupled to the i-th suppression candidate pin in one of the plurality of components different from the component including the i-th suppression candidate pin, from the working table; and
when the (i+1)-th suppression candidate pin is retrieved,
changing the noise transfer number of the (i+1)-th suppression candidate pin from “indefinite value” to “i+1”,
determining whether an (i+1)-th noise amount on the (i+1)-th suppression candidate pin is equal to or larger than the predetermined value, and
when the (i+1)-th noise amount is equal to or larger than the predetermined value, extracting the (i+1)-th suppression candidate pin as the suppression target pin, setting suppression requirement information representing that suppression on the (i+1)-th suppression candidate pin is required in the operation table, and outputting the suppression requirement information from the outputting device; and
when the (i+1)-th noise amount is smaller than the predetermined value, setting suppression non-requirement information representing that suppression on the (i+1)-th suppression candidate pin is not required in the operation table, and outputting the suppression non-requirement information from the outputting device.

6. The non-transitory computer-readable recording medium according to claim 1, the process further comprising:
when the suppression component is already arranged at the extracted suppression target pin,
outputting information, indicating that a change in the suppression component is not required, from the outputting device.

7. The non-transitory computer-readable recording medium according to claim 1, the process further comprising:
when the suppression component is not arranged at the extracted suppression target pin,
outputting information, indicating that an addition of the suppression component is required, from the outputting device.

8. The non-transitory computer-readable recording medium according to claim 1, the process further comprising:
when the suppression component is arranged at the suppression candidate pin not being extracted as the suppression target pin,
outputting information, representing that the suppression component has to be removed, from the outputting device.

9. The non-transitory computer-readable recording medium according to claim 1, the process further comprising:
outputting the information about the extracted suppression target pin, along with a pattern diagram of the board generated by referring to a result of circuit design of the board, from the output device.

10. The non-transitory computer-readable recording medium according to claim 1, wherein the process further comprising:
outputting the information about the extracted suppression target pin, along with a system diagram of a power source and a clock of the board generated by referring to a result of circuit design of the board, from the output device.

11. An information processing device comprising:
a processor that assists in arrangement design of a suppression component to suppress electromagnetic noise and to be disposed on a board when the board is designed by arranging a plurality of components thereon; and
a memory that stores therein an association among a source pin that is a source of generating the electromagnetic noise, a suppression candidate pin on which a measure against the electromagnetic noise generated by the source pin is to be taken, and a noise amount of noise that acts on the suppression candidate pin and that is originated from the electromagnetic noise generated at the source pin, the association being obtained for each of the plurality of components, wherein
the processor extracts, based on the association stored in the memory, a suppression candidate pin having a noise amount equal to or larger than a predetermined value as a suppression target pin for which the suppression component is to be arranged from a plurality of the suppression candidate pins, and that outputs, from an output device, information about the suppression target pin extracted.

12. The information processing device according to claim 11, wherein:
the association is in a form of a library;
the library is previously generated by, for each of the plurality of components,
specifying two pins in the component through which the electromagnetic noise transfers as the source pin and the suppression candidate pin,
determining the noise amount on the suppression candidate pin by referring to a type of transferring of the electromagnetic noise from the source pin to the suppression candidate pin and physical positional relationship between the source pin and the suppression candidate pin, and
associating the specified source pin and the specified suppression candidate pin and the determined noise amount with one another.

13. The information processing device according to claim 12, wherein:
the library includes a noise transfer number that represents an order of transferring of the electromagnetic noise for each of the plurality of suppression candidate pins; and
in generating the library, a noise transfer number “1” is set for a suppression candidate pin corresponding to an output pin of a component that generates the electromagnetic noise and a noise transfer number “indefinite value” is set for the remaining suppression candidate pins.

14. The information processing device according to claim 13, wherein the processor:
expands the library, as an operation table, into a predetermined memory region of the memory;
retrieves a first suppression candidate pin having the noise transfer number being “1” from the operation table;
determines whether a first noise amount on the first suppression candidate pin retrieved is equal to or larger than the predetermined value;
when the first noise amount is equal to or larger than the predetermined value, extracts the first suppression candidate pin as the suppression target pin, sets suppression requirement information representing that suppression on the first suppression candidate pin is required in the operation table, and outputs the suppression requirement information from the outputting device; and
when the first noise amount is smaller than the predetermined value, sets suppression non-requirement information representing that suppression on the first suppression candidate pin is not required in the operation table, and outputs the suppression non-requirement information from the outputting device.

15. The information processing device according to claim 14, wherein the processor:
retrieves, as an (i+1)-th suppression candidate pin (where i is an integer of one or more), the suppression candidate pin associated as the source pin with an i-th suppression candidate pin in one of the plurality of components including the i-th suppression candidate pin or the suppression candidate pin associated with the source pin coupled to the i-th suppression candidate pin in one of the plurality of components different from the component including the i-th suppression candidate pin, from the working table; and
when the (i+1)-th suppression candidate pin is retrieved,
changes the noise transfer number of the (i+1)-th suppression candidate pin from “indefinite value” to “i+1”,
determines whether an (i+1)-th noise amount on the (i+1)-th suppression candidate pin is equal to or larger than the predetermined value, and
when the (i+1)-th noise amount is equal to or larger than the predetermined value, extracts the (i+1)-th suppression candidate pin as the suppression target pin, sets suppression requirement information representing that suppression on the (i+1)-th suppression candidate pin is required in the operation table, and outputs the suppression requirement information from the outputting device; and
when the (i+1)-th noise amount is smaller than the predetermined value, sets suppression non-requirement information representing that suppression on the (i+1)-th suppression candidate pin is not required in the operation table, and outputs the suppression non-requirement information from the outputting device.

16. A method for assisting in arrangement design of a suppression component to suppress electromagnetic noise and to be disposed on a board when the board is designed by arranging a plurality of components thereon, the method comprising:
at a computer,
extracting, based on an association among a source pin that is a source of generating the electromagnetic noise, a suppression candidate pin on which a measure against the electromagnetic noise generated by the source pin is to be taken, and a noise amount of noise that acts on the suppression candidate pin and that is originated from the electromagnetic noise generated at the source pin, the association being obtained for each of the plurality of components, a suppression candidate pin having a noise amount equal to or larger than a predetermined value as a suppression target pin for which the suppression component is to be arranged from a plurality of the suppression candidate pins; and
outputting, from an output device, information about the suppression target pin extracted.

17. The method according to claim 16, wherein:
the association is in a form of a library;
the library is previously generated by, for each of the plurality of components,
specifying two pins in the component through which the electromagnetic noise transfers as the source pin and the suppression candidate pin,
determining the noise amount on the suppression candidate pin by referring to a type of transferring of the electromagnetic noise from the source pin to the suppression candidate pin and physical positional relationship between the source pin and the suppression candidate pin, and
associating the specified source pin and the specified suppression candidate pin and the determined noise amount with one another.

18. The method according to claim 17, wherein:
the library includes a noise transfer number that represents an order of transferring of the electromagnetic noise for each of the plurality of suppression candidate pins; and
in generating the library, a noise transfer number “1” is set for a suppression candidate pin corresponding to an output pin of a component that generates the electromagnetic noise and a noise transfer number “indefinite value” is set for the remaining suppression candidate pins.

19. The method according to claim 18, further comprising:
expanding the library, as an operation table, into a predetermined memory region;
retrieving a first suppression candidate pin having the noise transfer number being “1” from the operation table;
determining whether a first noise amount on the first suppression candidate pin retrieved is equal to or larger than the predetermined value;
when the first noise amount is equal to or larger than the predetermined value, extracting the first suppression candidate pin as the suppression target pin, setting suppression requirement information representing that suppression on the first suppression candidate pin is required in the operation table, and outputting the suppression requirement information from the outputting device; and
when the first noise amount is smaller than the predetermined value, setting suppression non-requirement information representing that suppression on the first suppression candidate pin is not required in the operation table, and outputting the suppression non-requirement information from the outputting device.

20. The method according to claim 19, further comprising
retrieving, as an (i+1)-th suppression candidate pin (where i is an integer of one or more), the suppression candidate pin associated as the source pin with an i-th suppression candidate pin in one of the plurality of components including the i-th suppression candidate pin or the suppression candidate pin associated with the source pin coupled to the i-th suppression candidate pin in one of the plurality of components different from the component including the i-th suppression candidate pin, from the working table; and
when the (i+1)-th suppression candidate pin is retrieved,
changing the noise transfer number of the (i+1)-th suppression candidate pin from “indefinite value” to “i+1”,
determining whether an (i+1)-th noise amount on the (i+1)-th suppression candidate pin is equal to or larger than the predetermined value, and
when the (i+1)-th noise amount is equal to or larger than the predetermined value, extracting the (i+1)-th suppression candidate pin as the suppression target pin, setting suppression requirement information representing that suppression on the (i+1)-th suppression candidate pin is required in the operation table, and outputting the suppression requirement information, from the outputting device; and
when the (i+1)-th noise amount is smaller than the predetermined value, setting suppression non-requirement information representing that suppression on the (i+1)-th suppression candidate pin is not required in the operation table, and outputting the suppression non-requirement information from the outputting device.
